(19) United States
(12) Patent Application Publication
(10) Pub. No.: US 2025/0159978 A1
(43) Pub. Date: May 15, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Chih-Yang CHEN, Hsinchu City (TW)

(21) Appl. No.: 18/509,545

(22) Filed: Nov. 15, 2023

(51) Int. Cl. H01L 27/092; H01L 21/822; H01L 21/8238; H01L 23/528; H01L 29/06; H01L 29/417; H01L 29/423; H01L 29/49; H01L 29/66; H01L 29/775

(52) U.S. Cl. CPC H10D 84/856; H01L 23/5286; H10D 30/014; H10D 30/43; H10D 30/6729; H10D 30/6735; H10D 30/6739; H10D 62/121; H10D 84/0167; H10D 84/017; H10D 84/0177; H10D 84/0186; H10D 84/038; H10D 88/01

(57) ABSTRACT

A semiconductor structure is provided. The semiconductor structure includes a bottom transistor, and a top transistor above the bottom transistor. The bottom transistor includes a plurality of first nanostructures, a first source/drain feature adjoining the first nanostructures and a first gate stack wrapping the first nanostructures. The top transistor includes a plurality of second nanostructures, a second source/drain feature adjoining the second nanostructures and a second gate stack wrapping the second nanostructures, wherein a first thickness of the first nanostructures is different than a second thickness of the second nanostructures. The semiconductor structure further includes an interlayer dielectric layer interposing between the first source/drain feature and the second source/drain feature.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary FET (CFET) have been introduced. In a CFET structure, nMOS and pMOS devices are stacked on top of each other, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIG. 3A is a cross-sectional view illustrating the formation of a semiconductor structure at one of the intermediate stages, in accordance with some embodiments of the disclosure.

FIG. 3B is a cross-sectional view illustrating the formation of a semiconductor structure at one of the intermediate stages corresponding to line Y1-Y1 or line Y2-Y2 of FIG. 2, in accordance with some embodiments of the disclosure.

FIGS. 3C-1, 3C-2 and 3C-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3D-1, 3D-2 and 3D-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3E-1, 3E-2 and 3E-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3F-1, 3F-2 and 3F-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3G-1, 3G-2 and 3G-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3H-1, 3H-2 and 3H-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 3I-1, 3I-2 and 3I-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 4-1, 4-2 and 4-3 are a modification of the semiconductor structure of FIGS. 3I-1, 3I-2 and 3I-3, in accordance with some embodiments of the disclosure.

FIGS. 5-1, 5-2 and 5-3 are a modification of the semiconductor structure of FIGS. 3I-1, 3I-2 and 3I-3, in accordance with some embodiments of the disclosure.

FIGS. 6-1, 6-2 and 6-3 are a modification of the semiconductor structure of FIGS. 3I-1, 3I-2 and 3I-3, in accordance with some embodiments of the disclosure.

FIGS. 7-1, 7-2 and 7-3 are a modification of the semiconductor structure of FIGS. 6-1, 6-2 and 6-3, in accordance with some embodiments of the disclosure.

FIGS. 8-1, 8-2 and 8-3 are a modification of the semiconductor structure of FIGS. 6-1, 6-2 and 6-3, in accordance with some embodiments of the disclosure.

FIGS. 9-1, 9-2 and 9-3 are a modification of the semiconductor structure of FIGS. 3I-1, 3I-2 and 3I-3, in accordance with some embodiments of the disclosure.

FIGS. 10-1, 10-2 and 10-3 are a modification of the semiconductor structure of FIGS. 6-1, 6-2 and 6-3, in accordance with some embodiments of the disclosure.

FIGS. 11-1, 11-2 and 11-3 are a modification of the semiconductor structure of FIGS. 9I-1, 9I-2 and 9I-3, in accordance with some embodiments of the disclosure.

FIGS. 12-1, 12-2 and 12-3 are a modification of the semiconductor structure of FIGS. 10-1, 10-2 and 10-3, in accordance with some embodiments of the disclosure.

FIGS. 13A-1, 13A-2 and 13A-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 13B-1, 13B-2 and 13B-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 13C-1, 13C-2 and 13C-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 13D-1, 13D-2 and 13D-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 13E-1, 13E-2 and 13E-3 are cross-sectional views the of formation of a semiconductor structure at one of the intermediate stages corresponding to line X-X, line Y1-Y1 and line Y2-Y2 of FIG. 2, in accordance with some embodiments of the disclosure.

FIGS. 14-1, 14-2 and 14-3 are a modification of the semiconductor structure of FIGS. 13E-1, 13E-2 and 13E-3, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of semiconductor structures and methods for forming the same are provided. The semiconductor structures may include a number of complementary field-effect transistor (CFET) structures, and each of the CFET structures may include a set of transistors, including a bottom transistor and a top transistor vertically stacked. The thickness of the channel layers of the top transistor is different than the thickness of the channel layers of the bottom transistor, and thus the performance of the top transistor and that of the bottom transistor can be independently adjusted. Therefore, a greater design flexibility for integrated circuits may be achieved.

In addition, the top transistor and the bottom transistor may further have different channel numbers, channel materials, channel width, and/or gate electrode materials, in accordance with some embodiments. Therefore, depending on the types of the resulting integrated circuits, the performance of integrated circuits can be improved by optimally adjusting these differences.

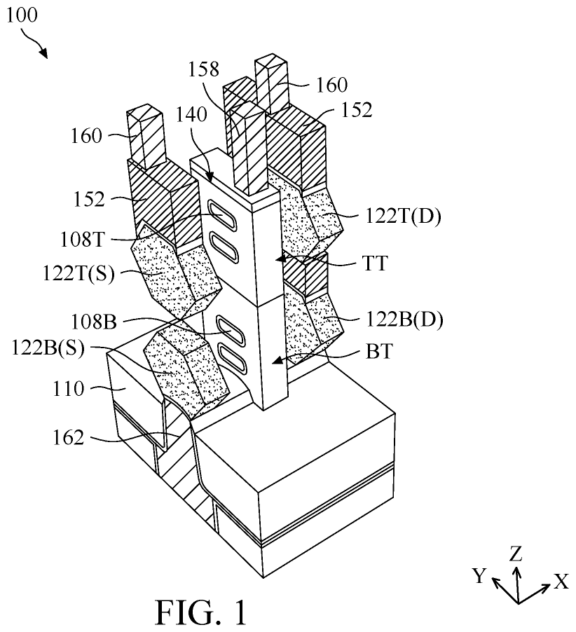

FIG. 1 is a perspective view of a semiconductor structure 100, in accordance with some embodiments. The semiconductor structure 100 includes a fin element (not shown), 7 an isolation structure 110 surrounding the fin element, a bottom transistor BT above the fin element, and a top transistor TT directly above the bottom transistor BT, in accordance with some embodiments. Both the top transistor TT and the bottom transistor BT are nanostructure transistors such as GAA transistors, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate. The Y-axis is transverse (e.g., substantially perpendicular) to the X-axis. The Z-axis is generally oriented along the vertical direction that is perpendicular to the main surface of the substrate (or the X-Y plane).

In some embodiments, the bottom transistor BT is a p-channel FET, and the top transistor TT is an n-channel FET. In some other embodiments, the bottom transistor BT is an n-channel FET, and the top transistor TT is a p-channel FET. The semiconductor structure 100 may be used to form STD cells e.g., CMOS inventor, NADN, NOR, AND, OR, Flip-Flop, and/or SCAN cell regions, and/or memory cells such as SRAM.

The bottom transistor BT includes a plurality of nanostructures 108B, bottom source/drain features 122B (including 122B(S) for the source terminal and 122B(D) for the drain terminal) adjoining the nanostructures 108B, and the bottom portion of a gate stack 140 wrapped around the nanostructures 108B, in accordance with some embodiments. The top transistor TT includes a plurality of nanostructures 108T, top source/drain features 122T (including the 122T(S) for the source terminal and 122T(D) for the drain terminal) adjoining the nanostructures 108T, and the top portion of the gate stack 140 wrapped around the nanostructures 108T, in accordance with some embodiments.

The semiconductor structure 100 also includes frontside contact plugs 152 landing on the top source/drain features 122T(S), 122T(D) and 122B(D), a gate via 158 landing on the gate stack 140, and a source/drain via 160 landing on the contact plugs 152, in accordance with some embodiments.

The semiconductor structure 100 also includes a backside contact plug 162 which is formed in the fin element and abuts the backside surface of the source/drain feature 122B(S). In some embodiments where the bottom transistor BT is a p-channel FET, and the top transistor TT is an n-channel FET, the top source/drain features 122T(S) of the top transistor TT is electrically connected to a VSS frontside power rail formed in a frontside metal layer (not shown), and the source/drain features 122B(S) of the bottom transistor BT is electrically connected to a VDD backside power rail formed in a backside metal layer (not shown).

The top source/drain features 122T(S) and the source/drain features 122B(S) are electrically isolated from each other, in accordance with some embodiments. In some other embodiments, the source/drain features 122B(S) of the bottom transistor BT may be electrically connected to a VDD frontside power rail. In some embodiments, the source/drain features 122T(D) and 122B(D) are electrically connected to each other through the contact plug 152.

The nanostructures 108B/108T extend between the source/drain features 122B/122T in the X direction, in accordance with some embodiments. The nanostructures 108B and 108T function as the channels of the transistors BT and TT, in accordance with some embodiments. The X direction may also be referred to as the channel-extending direction. The current of the resulting semiconductor device (i.e., nanostructure transistor) flows in the X direction through the channels. In this disclosure, a source/drain refers to a source and/or a drain. It is noted that in the present disclosure, a source and a drain are interchangeably used and the structures thereof are substantially the same.

The gate stack 140 is formed with longitudinal axes parallel to the Y direction and extending across and/or surrounding the nanostructures 108B and 108T, in accordance with some embodiments. The Y direction may also be referred to as a gate-extending direction, in accordance with some embodiments. In some embodiments, the top portion of the gate stack 140 for the top transistor TT is physically and electrically connected to the bottom portion of the gate stack 140 for the bottom transistor BT. In some other embodiments, the top portion of the gate stack 140 for the top transistor TT is physically and electrically isolated from the bottom portion of the gate stack 140 for the bottom transistor BT.

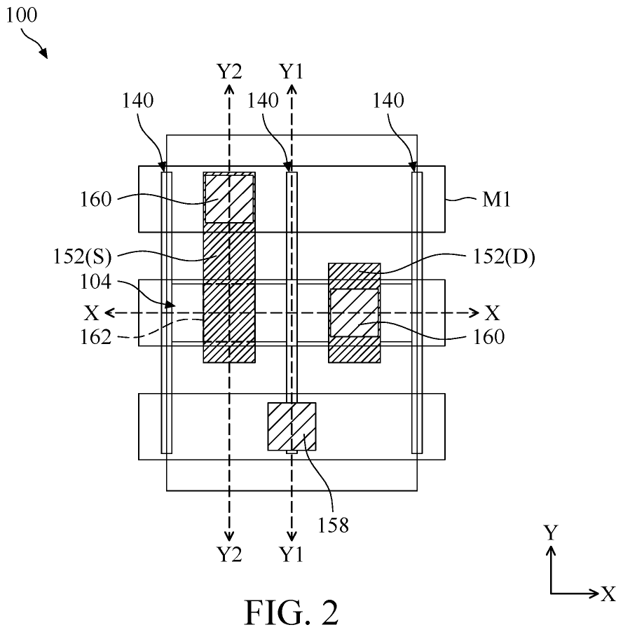

FIG. 2 illustrates the layout of the semiconductor structure 100, in accordance with some embodiments.

The semiconductor structure 100 includes an active region 104, and gate stacks 140 across the active region 104, in accordance with some embodiments. The active region 104 extends in the X direction, in accordance with some embodiments. The active region 104 includes a lower fin element and nanostructures (e.g., nanostructures 108B and 108T shown in FIG. 1) over the lower fin element, in accordance with some embodiments. The gate stacks 140 extend in the Y direction and across the lower fin elements, and wrap around the nanostructures of the active region 104, in accordance with some embodiments. The final gate stacks 140 are combined with the nanostructures of the active regions 104 to form nanostructure transistors (e.g., bottom transistor BT and top transistor TT in FIG. 1), in accordance with some embodiments.

Frontside contact plugs 152 (including 152(S) for the source terminal and 152(D) for the drain terminal) are disposed on the source/drain regions of the active region 104, in accordance with some embodiments. The contact plugs 152 are electrically connected to a frontside metal layer M1 where the contact plug 152(S) serves as a Vdd/Vss node and is electrically connected to a frontside power supply line through a via 160, and the contact plug 152(D) serves as a non-Vdd/Vss node and is electrically connected to a signal line through a via 160, in accordance with some embodiments. The gate stack 140 is electrically connected to the frontside metal layer M1 through a via 160, in accordance with some embodiments.

A backside contact plug 162 is disposed on the backside of the source/drain region of the active region 104, in accordance with some embodiments. The backside contact plug 162 serves as a Vdd/Vss node and is electrically connected to a backside power rail.

FIG. 2 further illustrates reference cross-sections that are used in later figures. Cross-section X-X is in a plane parallel to the longitudinal axis (X direction) of the active region 104 and through the active region 104, in accordance with some embodiments. Cross-section Y1-Y1 is in a plane parallel to the longitudinal axis (Y direction) of the gate stack 140 and through the gate stack 140, in accordance with some embodiments. Cross-section Y2-Y2 is in a plane parallel to the longitudinal axis (Y direction) of the gate stack 140 and through across the Vdd/Vss nodes of the source/drain region of the active region 104, in accordance with some embodiments.

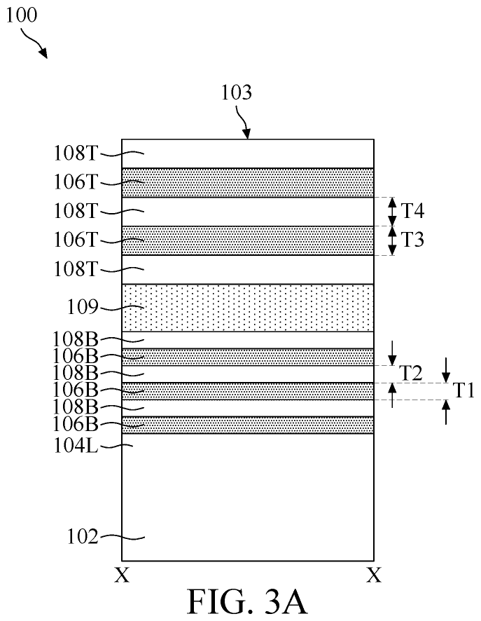

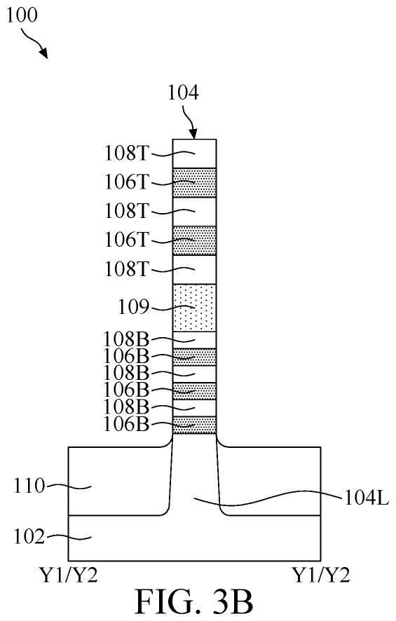

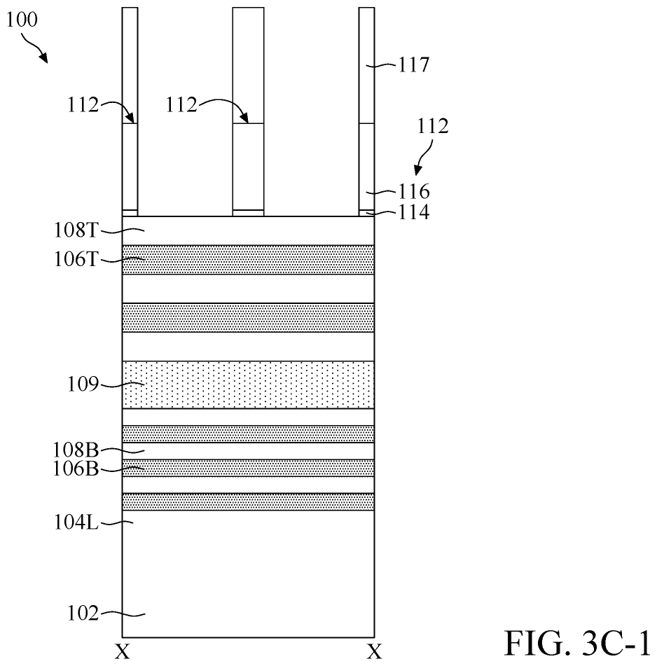

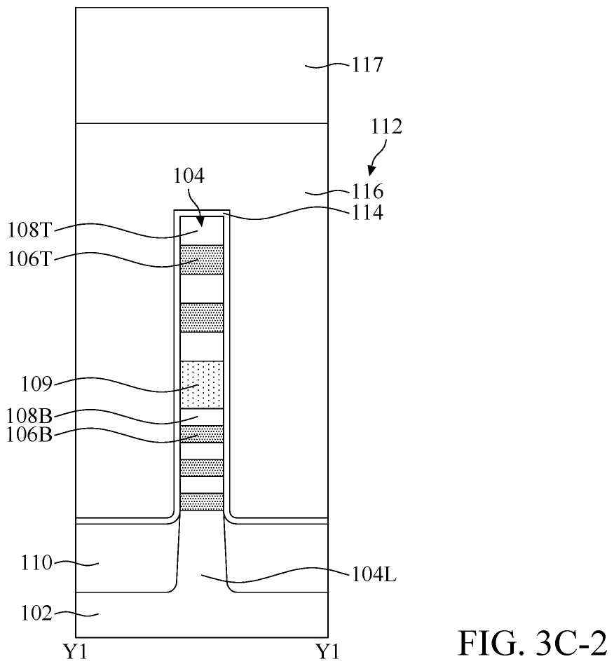

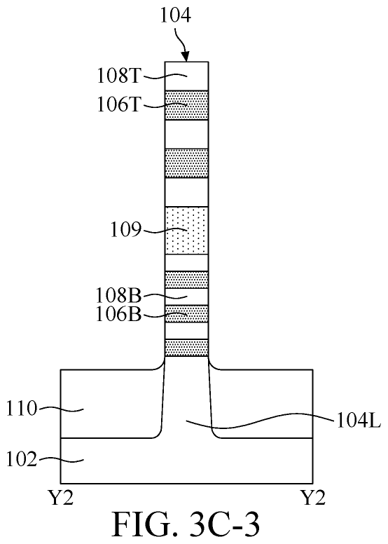

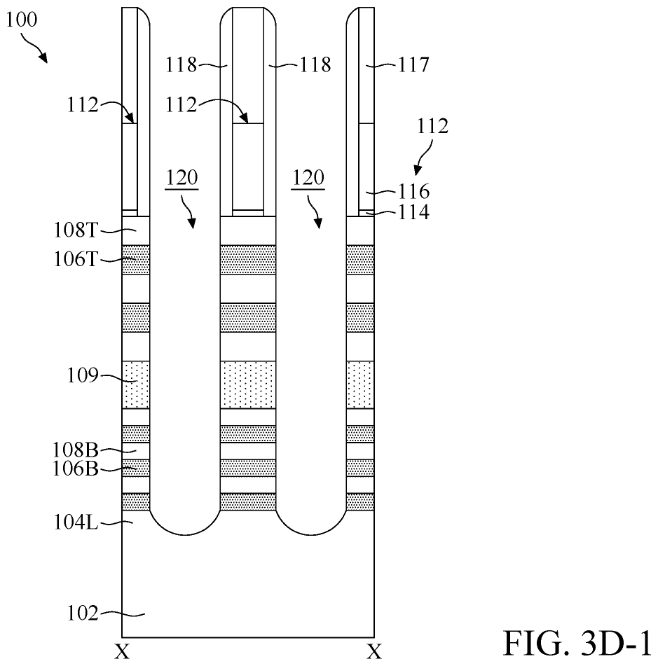

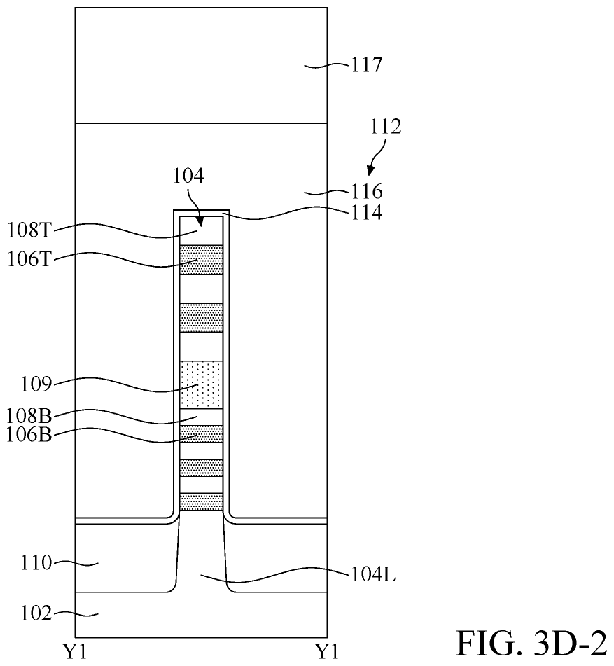

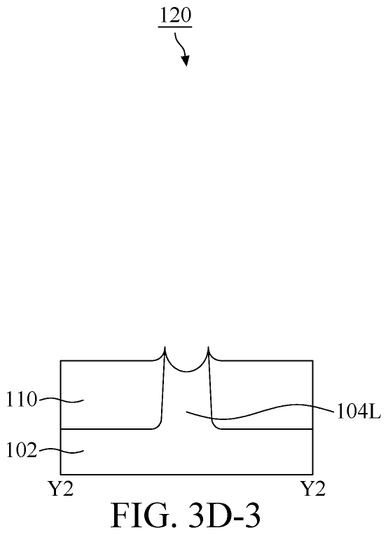

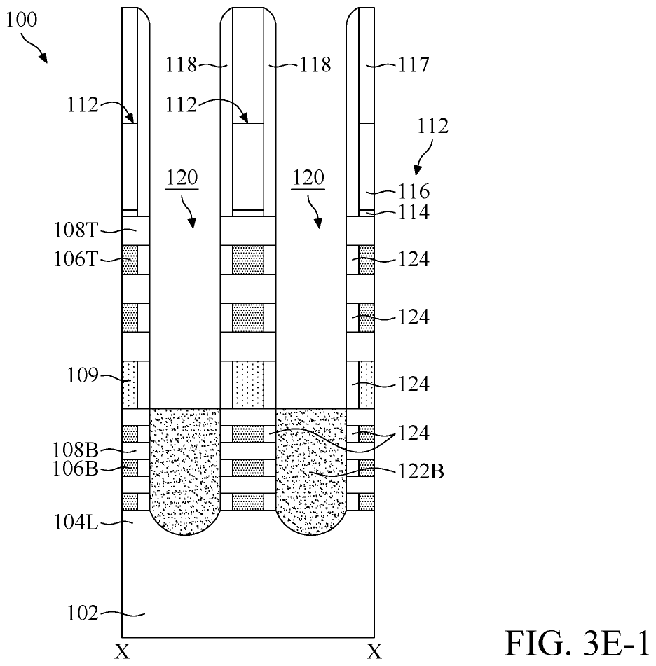

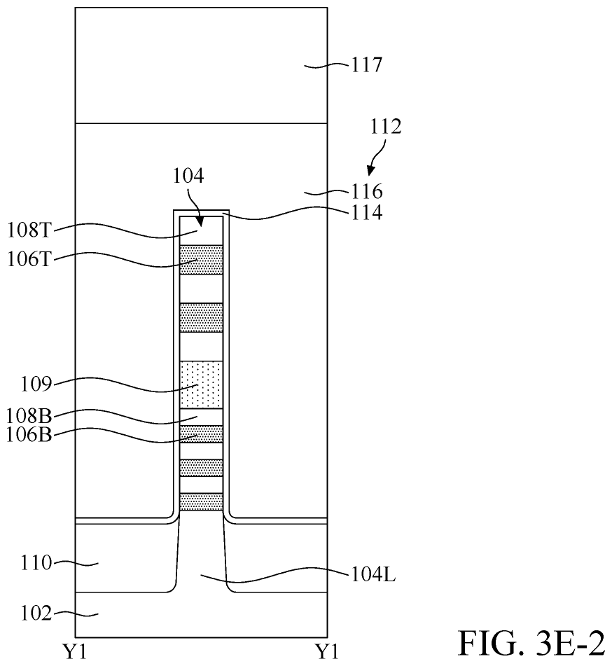

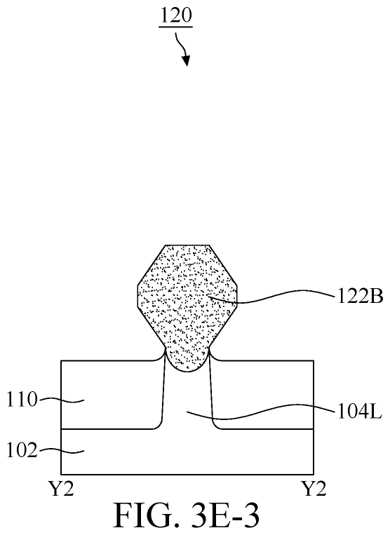

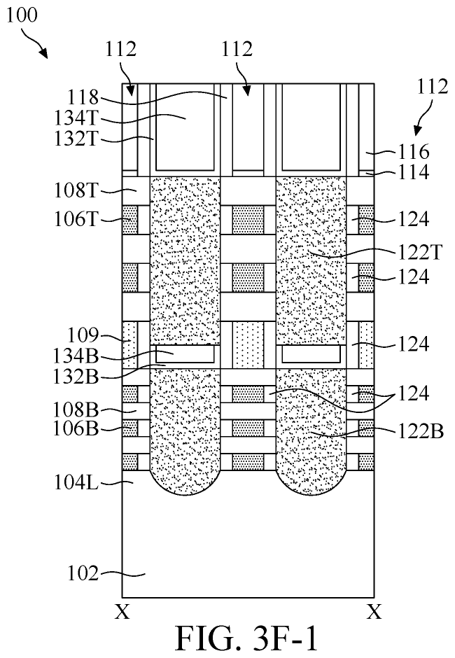

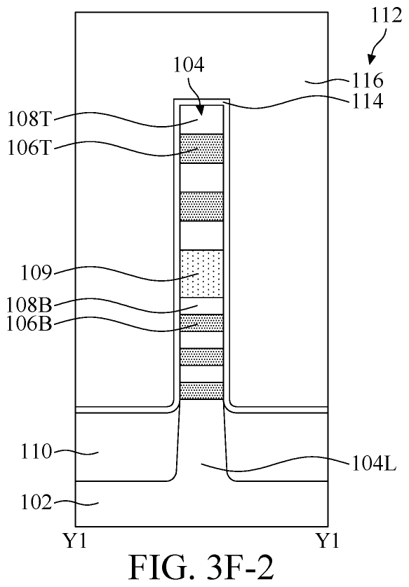

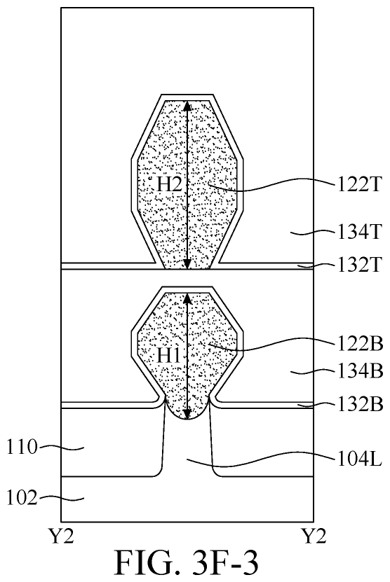

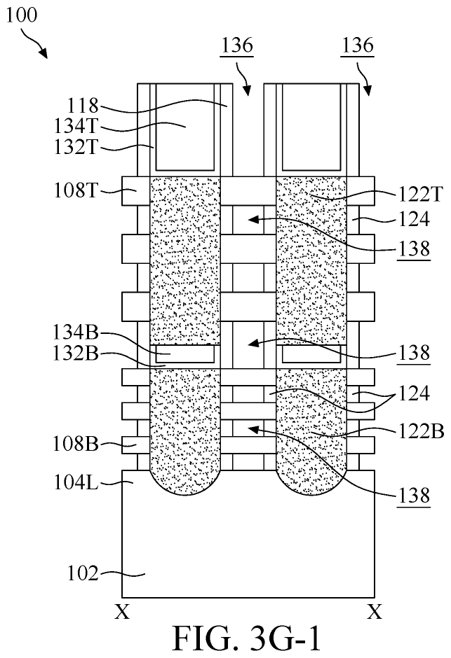

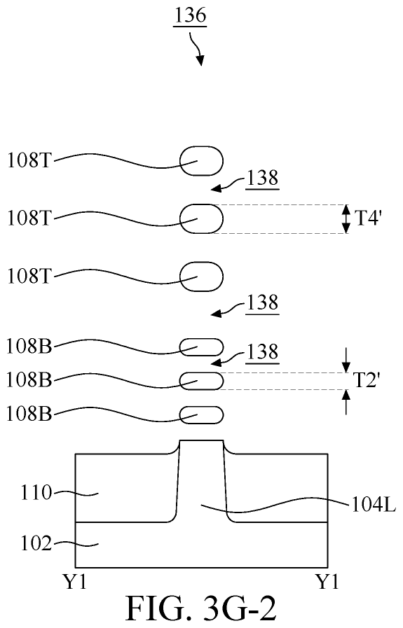

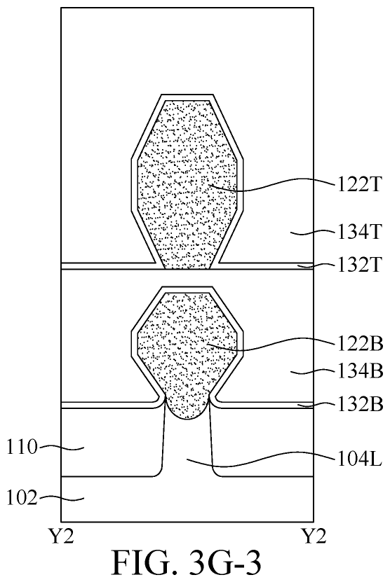

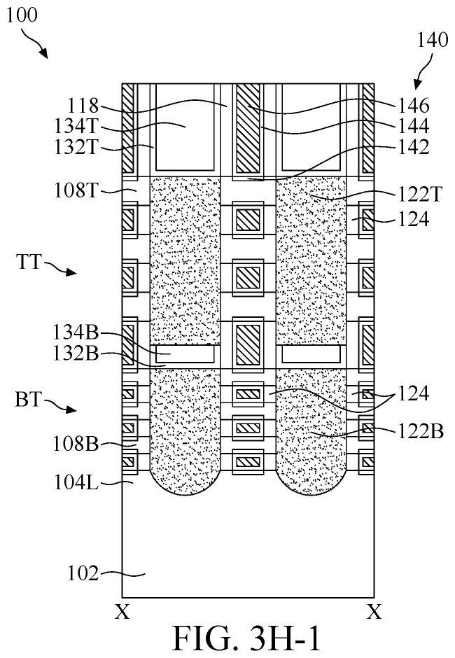

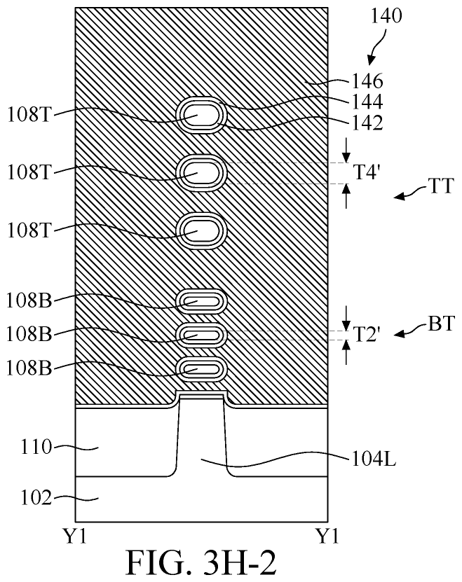

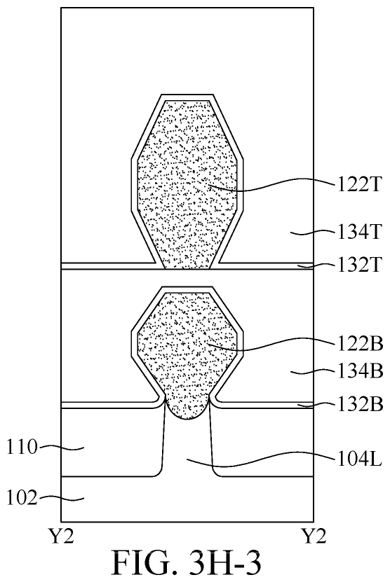

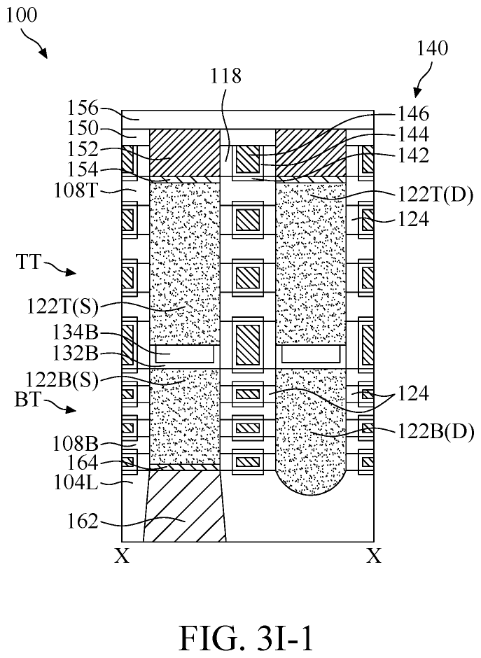

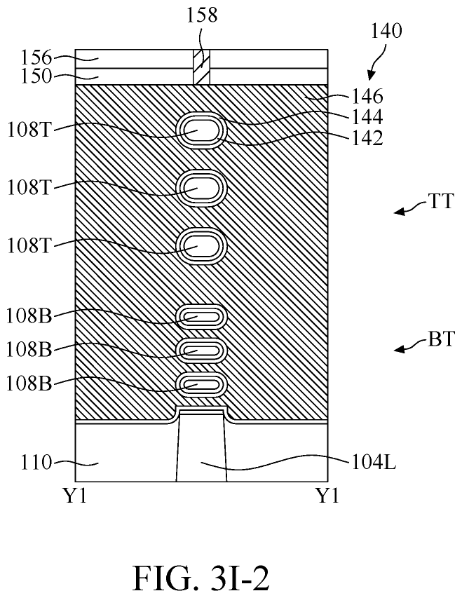

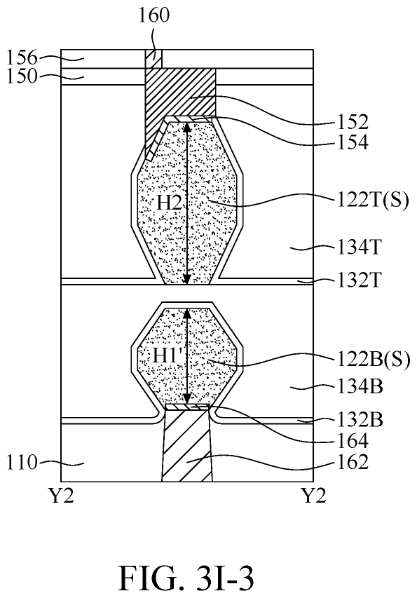

FIGS. 3A through 3G-3 are cross-sectional views illustrating the formation of the semiconductor structure 100 of FIG. 2 at various intermediate stages, in accordance with some embodiments of the disclosure. FIGS. 3C-1, 3D-1, 3E-1, 3F-1, 3G-1, 3H-1 and 3I-1 correspond to line X-X of FIG. 2, FIGS. 3B, 3C-2, 3D-2, 3E-2, 3F-2, 3G-2, 3H-2 and 3I-2 correspond to line Y1-Y1 of FIG. 2, and FIGS. 3B, 3C-3, 3D-3, 3E-3, 3F-3, 3G-3, 3H-3 and 3I-3 correspond to line Y2-Y2 of FIG. 2, in accordance with some embodiments of the disclosure.

FIG. 3A illustrates the semiconductor structure 100 after the formation of a stack 103, in accordance with some embodiments.

The semiconductor structure 100 includes a substrate 102 and a stack 103 formed over the substrate 102, as shown in FIG. 3A, in accordance with some embodiments. The semiconductor structure 100 is used to form CFET devices in which n-type devices and p-type devices are stacked on top of each other.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The stack 103 is formed using an epitaxial growth process, in accordance with some embodiments. The epitaxial growth process may be molecular beam epitaxy (MBE), metal organic chemical vapor deposition (MOCVD), vapor phase epitaxy (VPE), or another suitable technique. The stack 103 is a multi-layered structure which includes first semiconductor layer 106B and 106T, second semiconductor layers 108B and 108T, and a middle layer 109, in accordance with some embodiments.

In some embodiments, the first semiconductor layers 106B and 106T are made of a first semiconductor material, and the second semiconductor layers 108B and 108T are made of a second semiconductor material with a different composition than the first semiconductor material. The first semiconductor material for the first semiconductor layers 106B and 106T has a different lattice constant than the second semiconductor material for the second semiconductor layers 108B and 108T, in accordance with some embodiments. In some embodiments, the first semiconductor material and the second semiconductor material have different oxidation rates and/or etching selectivity.

In some embodiments, the first semiconductor layers 106B and 106T are made of SiGe, where the percentage of germanium (Ge) in the SiGe is in a range from about 20 atomic % to about 50 atomic %, and the second semiconductor layers 108B and 108T are made of pure or substantially pure silicon. In some embodiments, the first semiconductor layers 106B and 106T are Si₁₋ₓGeₓ, where x is more than about 0.3, or Ge (x=1.0) and the second semiconductor layers 108B and 108T are Si or Si_{1-y}Ge_{y}, where y is less than about 0.4, and x>y.

In some embodiments, the second semiconductor layers 108B and the second semiconductor layers 108T are made of the same material, such as Si. In some embodiments, the second semiconductor layers 108B and the second semiconductor layers 108T are made of different materials depending on the overall performance of the resulting CFET devices, for example, the second semiconductor layers 108B are made of SiGe, and the second semiconductor layers 108T are made of Si.

In some embodiments, the middle layer 109 is made of the same material as the first semiconductor layers 106B and 106T, e.g., SiGe. In some embodiments, the middle layer 109 is a SiGe layer with a higher germanium concentration than the first semiconductor layers 106B and 106T.

The stack 103 includes a bottom device region and a top device region above the bottom device region, where the middle layer 109 is interposed between the bottom device region and the top device region, in accordance with some embodiments. The bottom device region includes the semiconductor layers 106B and 108B while the top device region includes the semiconductor layers 106T and 108T, in accordance with some embodiments.

In some embodiments, the bottom device region is used to form p-type devices (e.g., p-channel nanostructure transistors), and the top device region is used to form n-type devices (e.g., n-channel nanostructure transistors). In some other embodiments, the bottom device region is used to form n-type devices (e.g., n-channel nanostructure transistors), and the top device region is used to form p-type devices (e.g., p-channel nanostructure transistors).

The bottom device region of the stack 103 is formed by depositing a first semiconductor layer 106B on the substrate 102, depositing a second semiconductor layer 108B on the first semiconductor layer 106B, and repeating the cycle of depositing the semiconductor layers 106B and 108B several times. As such, the first semiconductor layers 106B and the second semiconductor layers 108B are alternately stacked vertically, in accordance with some embodiments. The middle layer 109 is then formed on the topmost layer (e.g., the topmost layer 108B) of the bottom device region, in accordance with some embodiments.

In some embodiments, each of the first semiconductor layers 106B in the bottom device region has a thickness T1 in a range from about 5 nm to about 20 nm. In some embodiments, each of the second semiconductor layers 108B in the bottom device region has a thickness T2 in a range from about 2 nm to about 9 nm.

The top device region of the stack 103 is formed by depositing a second semiconductor layer 108T on the middle layer 109, depositing a first semiconductor layer 106T on the first semiconductor layer 106T, and repeating the cycle of depositing the semiconductor layers 108T and 106T several times. As such, the first semiconductor layers 106T and the second semiconductor layers 108T are alternately stacked vertically, in accordance with some embodiments. Although FIG. 3A illustrates that the number of the first semiconductor layer 106T is one less than the number of the second semiconductor layer 108T, the number of the first semiconductor layer 106T may be the same as the number of the second semiconductor layer 108T.

In some embodiments, each of the first semiconductor layers 106T in the top device region has a thickness T3 in a range from about 5 nm to about 20 nm. In some embodiments, each of the second semiconductor layers 108T in the top device region has a thickness T4 in a range from about 3 nm to about 10 nm.

In some embodiments, the second semiconductor layers 108T in the top device region are thicker than the second semiconductor layers 108B in the bottom device region, i.e., T4>T2. In some embodiments, the ratio of the thickness T4 to thickness T2 is greater than 1 and less than 5, e.g., in a range from about 1.1 to about 3.

In some embodiments, the first semiconductor layers 106T in the top device region is thicker than the first semiconductor layers 106B in the bottom device region, i.e., T3>T1. In some embodiments, the ratio of the thickness T4 to thickness T2 is greater than 1 and less than 4, e.g., in a range from about 1.1 to about 3.

In some other embodiments, the second semiconductor layers 108T in the top device region is thinner than the second semiconductor layers 108B in the bottom device region (i.e., T4<T2), and the first semiconductor layers 106T in the top device region is thinner than the first semiconductor layers 106B in the bottom device region (i.e., T3<T1).

Although three second semiconductor layers 108B and three second semiconductor layers 108T are shown in FIG. 3A, the numbers are not limited to three, and can be 1, 2, or more than 3, and is less than 10. In some embodiments, the number of the second semiconductor layers 108B is the same as the number of the second semiconductor layers 108T. In some other embodiments, the number of the second semiconductor layers 108B may be different than the number of the second semiconductor layers 108T.

The first semiconductor layers 106B and 106T and the middle layer 109 are configured as sacrificial layers and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments.

FIG. 3B illustrates the semiconductor structure 100 after the formation of an active region 104 and an isolation structure 110, in accordance with some embodiments.

A patterning process is performed on the stack 103 and underlying substrate 102 using photolithography and etching processes, thereby forming trenches and an active region 104 protruding from between trenches, in accordance with some embodiments. The portion of the substrate 102 protruding from between the trenches serves as a lower fin element 104L of the active region 104, in accordance with some embodiments. The remainder of the epitaxial stack 103 serves as the upper fin element of the active region 104, in accordance with some embodiments. In some embodiments, the active region 104 may be referred to a fin or a fin structure.

In some embodiments, the active region 104 extends in the X direction. The active region 104 has a longitudinal axis parallel to the X direction, in accordance with some embodiments. Although one active region 104 is shown in FIG. 3B, the number of the active region 104 is not limited thereto, and may depend on the performance and design demands of the resulting semiconductor device.

An isolation structure 110 is formed to surround the lower fin element 104L of the active region 104, as shown in FIG. 3B, in accordance with some embodiments. The isolation structure 110 is configured to electrically isolate neighboring active regions 104 and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) to expose the sidewalls of the upper fin element of the active region 104, in accordance with some embodiments. The remaining insulating material serves as the isolation structure 110, in accordance with some embodiments.

FIGS. 3C-1, 3C-2 and 3C-3 illustrate the semiconductor structure 100 after the formation of dummy gate structures 112, in accordance with some embodiments.

Dummy gate structures 112 are formed across the active region 104 and the isolation structure 110, as shown in FIGS. 3C-1 and 3C-2, in accordance with some embodiments. The dummy gate structures 112 are configured as sacrificial structures and will be replaced with the final gate stacks, in accordance with some embodiments. In some embodiments, the dummy gate structures 112 extend in the Y direction. That is, the dummy gate structures 112 have longitudinal axes parallel to the Y direction, in accordance with some embodiments. The dummy gate structures 112 surround the channel regions of the active region 104, in accordance with some embodiments.

Each of the dummy gate structures 112 includes a dummy gate dielectric layer 114 and a dummy gate electrode layer 116 formed over the dummy gate dielectric layer 114, as shown in FIGS. 3C-1 and 3C-2, in accordance with some embodiments. In some embodiments, the dummy gate dielectric layer 114 is conformally formed along the upper fin element of the active region 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112.

The patterning process includes forming a patterned hard mask layer 117 over the material for the dummy gate electrode layer 116, in accordance with some embodiments. The patterned hard mask layer corresponds to and overlaps the channel regions of the active region 104, in accordance with some embodiments. The materials for the dummy gate dielectric layer 114 and the dummy gate electrode layer 116, uncovered by the patterned hard mask layer, are etched away until the active region 104 and the top surface of the isolation structure 110 are exposed, in accordance with some embodiments

FIGS. 3D-1, 3D-2 and 3D-3 illustrate the semiconductor structure 100 after the formation of gate spacer layers 118 and source/drain recesses 120, in accordance with some embodiments.

Gate spacer layers 118 are formed along opposite sidewalls of the dummy gate structures 112, as shown in FIG. 3D-1, in accordance with some embodiments. The gate spacer layers 118 extend in the Y direction and across the active regions 104 and the isolation structure 110, in accordance with some embodiments. The gate spacer layers 118 are used to offset the subsequently formed source/drain features and separate the source/drain features from the gate structure, in accordance with some embodiments.

In some embodiments, the formation of the gate spacer layers 118 includes globally and conformally depositing a dielectric material over the semiconductor structure 100 using atomic layer deposition (ALD), CVD (such as LPCVD, PECVD, HDP-CVD and HARP), another suitable method, and/or a combination thereof, followed by an anisotropic etching process. In some embodiments, the etching process is performed without an additional photolithography process. In some embodiments, the gate spacer layers 118 may be silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. The vertical portions of the dielectric material left remaining on the opposite sides of the dummy gate structures 112 serve as the gate spacer layers 118, in accordance with some embodiments.

An etching process is performed to recess the source/drain regions of the active region 104, thereby forming source/drain recesses 120, as shown in FIGS. 3D-1 and 3D-3, in accordance with some embodiments. The etching process may be an anisotropic etching process such as dry plasma etching, an isotropic etching process such as dry chemical etching, remote plasma etching or wet chemical etching, and/or a combination thereof.

The gate spacer layers 118 and the dummy gate structures 112 may serve as etch masks such that the source/drain recesses 120 are formed self-aligned on opposite sides of the dummy gate structures 112, as shown in FIG. 3D-3. in accordance with some embodiments. The source/drain recesses 120 extend a distance into the lower fin element 104L, in accordance with some embodiments.

FIGS. 3E-1, 3E-2 and 3E-3 illustrate the semiconductor structure 100 after the formation of inner spacer layers 124 and bottom source/drain features 122B, in accordance with some embodiments.

An etching process is performed to laterally recess, from the source/drain recesses 120, the first semiconductor layers 106B and 106T and the middle layer 109 of the active region 104, thereby forming notches, and then inner spacer layers 124 are formed in the notches, as shown in FIG. 3E-1, in accordance with some embodiments. The inner spacer layers 124 abut the recessed side surfaces of the first semiconductor layers 106B and 106T and the middle layer 109, in accordance with some embodiments. The inner spacer layers 124 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 124 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 124 are formed by depositing a dielectric material to fill the notches, and then etching away the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

Bottom source/drain features 122B are grown from the exposed side surfaces of the second semiconductor layers 108B and the exposed top surface of the lower fin element 104L in the source/drain recesses 120 using an epitaxial growth process, as shown in FIGS. 3E-1 and 3E-3, in accordance with some embodiments. The epitaxial growth process may be MBE, MOCVD, or VPE, or another suitable technique. In some embodiments, a mask layer may be formed to cover the exposed side surfaces of the second semiconductor layers 108T to prevent epitaxial material formed on second semiconductor layers 108T. After the bottom source/drain features 122B are formed, the mask layer may be removed. Although the bottom source/drain features 122B are illustrated as having facet surfaces, the surface of the bottom source/drain features 122B may have curved in some other embodiments.

In some embodiments, the bottom source/drain features 122B are made of any suitable semiconductor material for n-type semiconductor devices or p-type semiconductor devices. In some embodiments, the bottom source/drain features 122B are doped. The concentration of the dopant in the bottom source/drain features 122B in a range from about 1×10¹⁹ cm⁻³ to about 6×10²¹ cm⁻³.

In some embodiments where the bottom device region of the active region 104 is to be formed as p-type devices (e.g., p-channel nanostructure transistors), the bottom source/drain features 122B are made of semiconductor material such as SiGe, Si, GaAs, another suitable semiconductor material, or a combination thereof. In some embodiments, the bottom source/drain features 122B are doped with the p-type dopant during the epitaxial growth process. For example, the p-type dopant may be boron (B) or BF₂. For example, the bottom source/drain features 122B may be the epitaxially grown SiGe doped with boron (B) to form silicon germanium:boron (SiGe:B) source/drain feature.

FIGS. 3F-1, 3F-2 and 3F-3 illustrate the semiconductor structure 100 after the formation of contact etching stop layers 132B and 132T, a top source/drain feature 122T and first interlayer dielectric layers 134B and 134T, in accordance with some embodiments.

A contact etching stop layer 132B is formed over the semiconductor structure 100 to cover the bottom source/drain features 122B, as shown in FIGS. 3F-1 and 3F-3, in accordance with some embodiments. In some embodiments, the contact etching stop layer 132B is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 132B is globally and conformally deposited over the semiconductor structure 100 using CVD (such as LPCVD, PECVD, HDP-CVD, or HARP), ALD, another suitable method, or a combination thereof.

Afterward, a first interlayer dielectric layer 134B is formed over the contact etching stop layer 132B, as shown in FIGS. 3F-1 and 3F-3, in accordance with some embodiments. The first interlayer dielectric layer 134B overfills the space between dummy gate structures 112, in accordance with some embodiments. In some embodiments, the first interlayer dielectric layer 134B is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the first interlayer dielectric layer 134B and the contact etching stop layer 132B are made of different materials and have a great difference in etching selectivity. In some embodiments, the dielectric material for the first interlayer dielectric layer 134B is deposited using such as CVD (such as HDP-CVD, PECVD, HARP or FCVD), another suitable technique, or a combination thereof. The dielectric materials for the contact etching stop layer 132B and the first interlayer dielectric layer 134B above the top surface of the dummy gate electrode layer 116 are removed using such as CMP, and then etched-back until the side surfaces of the middle layer 109 are exposed, in accordance with some embodiments. The patterned mask layer 117 may be also removed in the CMP process.

Top source/drain features 122T are grown from the exposed side surfaces of the second semiconductor layers 108T in the source/drain recesses 120 using an epitaxial growth process, as shown in FIGS. 3F-1 and 3F-3, in accordance with some embodiments. The epitaxial growth process may be MBE, MOCVD, or VPE, or another suitable technique. Although the top source/drain features 122T are illustrated as having facet surfaces, the surface of the top source/drain features 122T may have curved in some other embodiments.

In some embodiments, the top source/drain features 122T are made of any suitable semiconductor material for n-type semiconductor devices or p-type semiconductor devices. In some embodiments, the top source/drain features 122T are doped. The concentration of the dopant in the top source/drain features 122T in a range from about 1×10¹⁹ cm⁻³ to about 6×10²¹ cm⁻³.

In some embodiments where the top device region of the active region 104 is to be formed as n-type devices (e.g., n-channel nanostructure transistors), the top source/drain features 122T are made of semiconductor material such as SiP, SiAs, SiCP, SiC, Si, GaAs, another suitable semiconductor material, or a combination thereof. In some embodiments, the top source/drain features 122T are doped with the n-type dopant during the epitaxial growth process. For example, the n-type dopant may be phosphorous (P) or arsenic (As). For example, the top source/drain features 122T may be the epitaxially grown Si doped with phosphorous to form silicon:phosphor (Si:P) source/drain features and/or arsenic to form silicon:arsenic (Si:As) source/drain feature.

In some other embodiments where the bottom device region is used to form n-type devices and the top device region is used to form p-type devices, the bottom source/drain features 122B are doped with n-type dopants while the top source/drain features 122T are doped with p-type dopants. In some embodiments, the height H1 of the bottom source/drain features 122B is less than the height H2 of the top source/drain features 122T.

A contact etching stop layer 132T is formed over the semiconductor structure 100 to cover the top source/drain features 122T, and a first interlayer dielectric layer 134T is formed over the contact etching stop layer 132T, in accordance with some embodiments. In some embodiments, the material of the contact etching stop layer 132T and the first interlayer dielectric layer 134T may be the same as to similar to the material of the contact etching stop layer 132B and the first interlayer dielectric layer 134B, respectively.

The dielectric materials for the contact etching stop layer 132T and the first interlayer dielectric layer 134T above the top surface of the dummy gate electrode layer 116 are removed using such as CMP to expose the top surfaces of the dummy gate structures 112, in accordance with some embodiments.

FIGS. 3G-1, 3G-2 and 3G-3 illustrate the semiconductor structure 100 after the formation of gate trenches 136 and gaps 138, in accordance with some embodiments.

The dummy gate structures 112 are removed using an etching process to form gate trenches 136 between the gate spacer layers 118, as shown in FIGS. 3G-1 and 3G-2, in accordance with some embodiments. In some embodiments, the gate trenches 136 expose the channel regions of the active region 104 and the top surface of the isolation structure 110. In some embodiments, the gate trenches 136 further expose the sidewalls of the gate spacer layers 118 facing the channel regions. In some embodiments, the etching process includes plasma dry etching, a dry chemical etching, and/or a wet etching.

Afterward, an etching process is performed on the first semiconductor layers 106B and 106T and the middle layer 109 to form gaps 138, as shown in FIGS. 3G-1 and 3G-2, in accordance with some embodiments. In some embodiments, the gaps 138 expose the sidewalls of the inner spacer layers 124 facing the channel region. The inner spacer layers 124 may be used as an etching stop layer in the etching process, which may protect the source/drain features 122B and 122T from being damaged. In some embodiments, the etching process includes plasma dry etching, a dry chemical etching, and/or a wet etching.

After the etching processes, the main surfaces of the second semiconductor layers 108B and 108T are exposed, in accordance with some embodiments. The exposed second semiconductor layers 108B and 108T form nanostructures, in accordance with some embodiments. In some embodiments, a corner-rounding process may be performed on the nanostructures 108B and 108T. The nanostructures 108B and 108T are vertically stacked and spaced apart from one other, in accordance with some embodiments. The nanostructures 108B function as channels of the bottom devices of the CFET, and the nanostructures 108T function as channels of the top devices of the CFET, in accordance with some embodiments.

In some embodiments, each of the nanostructures 108B has a thickness T2′ in a range from about 2 nm to about 9 nm. In some embodiments, each of the nanostructures 108T has a thickness T4′ in a range from about 3 nm to about 10 nm. In some embodiments, the nanostructures 108T are thicker than the nanostructures 108B in the bottom device region, i.e., T4′>T2′. In some embodiments, the ratio of the thickness T4′ to thickness T2′ is greater than 1 and less than 5, e.g., in a range from about 1.1 to about 3.

FIGS. 3H-1, 3H-2 and 3H-3 illustrate the semiconductor structure 100 after the formation of final gate stacks 140, in accordance with some embodiments.

Final gate stacks 140 are formed in the gate trenches 136 and gaps 138, as shown in FIGS. 3H-1 and 3H-2, in accordance with some embodiments. The nanostructures 108B and 108T are wrapped by the final gate stacks 140, in accordance with some embodiments. In some embodiments, the final gate stacks 140 extend in the Y direction. The final gate stacks 140 have longitudinal axes parallel to the Y direction, in accordance with some embodiments. In some embodiments, each of the final gate stacks 140 includes an interfacial layer 142, a gate dielectric layer 144 and a metal gate electrode layer 146, as shown in FIGS. 3H-1 and 3H-3, in accordance with some embodiments.

The interfacial layer 142 is formed on the exposed surfaces of the nanostructures 108B and 108T, in accordance with some embodiments. The interfacial layer 142 wraps around the nanostructures 108B and 108T, in accordance with some embodiments. In some embodiments, the interfacial layer 142 is made of a chemically formed silicon oxide. In some embodiments, the interfacial layer 142 is nitrogen-doped silicon oxide. In some embodiments, the interfacial layer 142 is formed using one or more cleaning processes such as including ozone (03), ammonia hydroxide-hydrogen peroxide-water mixture, and/or hydrochloric acid-hydrogen peroxide-water mixture. Semiconductor material from the nanostructures 108 and the lower fin element 104L is oxidized to form the interfacial layer 142, in accordance with some embodiments.

The gate dielectric layer 144 is formed conformally along the interfacial layer 142 to be wrapped around the nanostructures 108B and 108T, in accordance with some embodiments. The gate dielectric layer 144 is also conformally formed along the sidewalls of the gate spacer layers 118 facing the channel regions, in accordance with some embodiments. The gate dielectric layer 144 is also conformally formed along the sidewalls of the inner spacer layers 124 facing the channel regions, in accordance with some embodiments.

The gate dielectric layer 144 may be high-k dielectric layer. In some embodiments, the high-k dielectric layer is dielectric material with high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layer 146 is formed to overfill remainders of the gate trenches 136 and gaps 138, in accordance with some embodiments. In some embodiments, the metal gate electrode layer 146 is made of more than one conductive material, such as a metal, metal alloy, conductive metal oxide and/or metal nitride, another suitable conductive material, and/or a combination thereof. For example, the metal gate electrode layer 146 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 146 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to the next layer, and a metal fill layer to reduce the total resistance of gate stacks, and/or another suitable layer. The metal gate electrode layer 146 may be formed using ALD, PVD, CVD, e-beam evaporation, or another suitable technique.

In some embodiments, the metal gate electrode layer 146 may be includes a single work function metal that continuously surrounds the nanostructures 108B and 108T. In some other embodiments where the bottom device region is used to form p-type devices and the top device region is used to form n-type devices, the metal gate electrode layer 146 includes a p-type work function metal surrounding the nanostructures 108B, and an n-type work function metal surrounding the nanostructures 108T.

A planarization process such as CMP may be performed on the semiconductor structure 100 to remove the materials of the gate dielectric layer 144 and the metal gate electrode layer 146 formed above the top surface of the first interlayer dielectric layer 134T, in accordance with some embodiments.

The bottom portion of the final gate stacks 140 that are wrapped around the bottom nanostructures 108B combine with the neighboring bottom source/drain features 122B to form bottom transistors BT, e.g., p-channel nanostructure transistors. The top portion of the final gate stacks 140 that are wrapped around the top nanostructures 108T combine with the neighboring top source/drain features 122T to form top transistors TT, e.g., n-channel nanostructure transistors.

The n-channel top transistors TT are directly stacked above the p-channel bottom transistors BT thereby constructing CFET. The final gate stacks 140 engage the channel region of the CFET so that current can flow between the source/drain features 122B/122T during operation. In some other embodiments, the top transistors TT are p-channel nanostructure transistors, and the bottom transistors BT are n-channel nanostructure transistors.

FIGS. 3I-1, 3I-2 and 3I-3 illustrate the semiconductor structure 100 after the formation of a second interlayer dielectric layer 150, contact plugs 152, a third interlayer dielectric layer 156, vias 158 and 160, and a backside contact plug 162, in accordance with some embodiments.

A second interlayer dielectric layer 150 is formed over the semiconductor structure 100, as shown in FIGS. 3I-1 to 3I-3, in accordance with some embodiments. In some embodiments, the second interlayer dielectric layer 150 is made of dielectric material, such as USG, BPSG, FSG, PSG, BSG, and/or another suitable dielectric material. In some embodiments, the second interlayer dielectric layer 150 is deposited using such as CVD (such as HDP-CVD, PECVD, HARP or FCVD), another suitable technique, or a combination thereof.

Contact plugs 152 are formed through the second interlayer dielectric layer 150, the first interlayer dielectric layer 134T and the contact etching stop layer 132T, as shown in FIGS. 3I-1 and 3I-3, in accordance with some embodiments. The contact plugs 152 land on and are electrically connected to the top source/drain features 122T(S) for the source terminal and the top source/drain features 122T(D) for the drain terminal, in accordance with some embodiments.

Although not shown, at the drain-terminal side, the contact plug 152 which connected to the top source/drain features 122T(D) may be further formed through the first interlayer dielectric layers 134B and the contact etching stop layers 132B, and land on and are electrically connected to the bottom source/drain feature 122B(D), in accordance with some embodiments. The contact plugs 152 may be also referred to as frontside contact plugs 152.

In some embodiments, the formation of the contact plugs 152 includes patterning the semiconductor structure 100 to form contact openings (where the contact plugs 152 are to be formed) using photolithography and etching processes until the source/drain features 122T and 122S are exposed. Silicide layers 154 are formed on the exposed surfaces of the source/drain features 122T and 122B. In some embodiments, the silicide layers 154 are made of WSi, NiSi, TiSi and/or CoSi. Afterward, one or more conductive materials for the contact plugs 152 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 150 are planarized using, for example, CMP.

The contact plugs 152 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

A third interlayer dielectric layer 156 is formed over the semiconductor structure 100, as shown in FIGS. 3I-1 to 3I-3, in accordance with some embodiments. In some embodiments, the third interlayer dielectric layer 156 is made of dielectric material, such as USG, BPSG, FSG, PSG, BSG, and/or another suitable dielectric material. In some embodiments, the third interlayer dielectric layer 156 is deposited using such as CVD (such as HDP-CVD, PECVD, HARP or FCVD), another suitable technique, or a combination thereof.

A via 158 is formed through the third interlayer dielectric layer 156 and the second interlayer dielectric layer 150 and lands on the final gate stack 140, and vias 160 are formed through the third interlayer dielectric layer 156 and land on the contact plugs 152, as shown in FIGS. 3I-1 to 3I-3, in accordance with some embodiments. The via 160 is electrically connected to the gate terminal, and may be also referred to as a gate via (VG), the vias 150 are electrically connected to the source/drain terminals, and may be also referred to as a source/drain vias (VS or VD), in accordance with some embodiments.

The formation of the vias 156 and 158 includes patterning the third interlayer dielectric layer 156 and the second interlayer dielectric layer 150 to form vias openings (where the vias 156 and 158 are to be formed) using one or more photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the third interlayer dielectric layer 156 are planarized using, for example, CMP.

The vias 156 and 158 may have a multilayer structure. For example, a barrier/adhesive layer (not shown) may optionally be deposited along the sidewalls and the bottom surfaces of the via openings. The barrier layer may be made of Ta, TaN, Ti, TiN, CoW, another suitable material, or a combination thereof. A metal bulk layer is then deposited on the barrier/adhesive layer (if formed) to fill the remainder of the via openings. In some embodiments, the metal bulk layers are made of one or more conductive materials, such as Co, Ni, W, Ti, Ta, Cu, Rh, Ir, Pt, Al, Ru, Mo, or a combination thereof.

The semiconductor structure 100 may undergo further frontside MEOL and/or BEOL processes to form various interconnection conductive features (not shown) over the semiconductor structure 100, such as frontside metal layers and vias between neighboring two metal layers.

A backside contact plug 162 is formed to abut the backside surface of the source/drain feature 122B(S) for the source terminal, as shown in FIGS. 3I-1 and 3I-3, in accordance with some embodiments. In some embodiments where the bottom transistor BT is a p-channel FET and the top transistor TT is an n-channel FET, the source terminal of the bottom transistor BT is electrically connected to a VDD power rail through the backside contact plug 162, and the source terminal of the top transistor TT is electrically connected to a VSS power rail through contact plug 152 and the via 160.

The formation of the backside contact plug 162 includes flipping the semiconductor structure 100 upside down, planarizing the backside of the semiconductor structure 100 using such as CMP to expose the isolation structure 110, patterning the lower fin element 104L using photolithography and etching processes to form an opening (where the backside contact plug 162 is to be formed) exposing bottom source/drain feature 122B(S). In some embodiments, the portion of the bottom source/drain feature 122B(S) extending into the fin element 104L may be also removed. In some embodiments, the bottom source/drain features 122B(S) has a height H1′ that is less than the height H2 of the top source/drain features 122T.

A silicide layer 164 is formed on the exposed backside surfaces of the bottom source/drain feature 122B(S). In some embodiments, the silicide layer 164 is made of WSi, NiSi, TiSi and/or CoSi. Afterward, one or more conductive materials (e.g., Ta, TaN, Ti, TiN, CoW, Co, Ni, W, Cu, Rh, Ir, Pt, Al, Ru, Mo, another suitable metal material, or a combination thereof) are deposited to overfill the opening, in accordance with some embodiments. The excess conductive material outside the opening is removed, for example, using CMP and/or an etching process.

The semiconductor structure 100 may undergo further backside BEOL processes to form various interconnection conductive features (not shown) over backside of the semiconductor structure 100, such as backside metal layers, vias between neighboring two metal layers, passivation layers, bump pads, etc.

In accordance with the embodiments of the present disclosure, each of the CFET devices of the semiconductor structure 100 includes a bottom transistor BT and a top transistor TT directly above the bottom transistor BT. The nanostructures 108T of the top transistor TT may be formed to have a different thickness than the nanostructures 108B of the bottom transistor BT, and thus the performance of the top transistor TT and that of the bottom transistor BT can be independently adjusted. For example, the top transistor TT with thickener nanostructures 108T may have a strong performance (e.g., lower channel resistance (RCH), better DC performance, etc.), while the bottom transistor BT with thinner nanostructures 108B may have a better gate control over the nanostructures 108B to improve DIBL.

Due to the independent adjustment of the performance of the n-channel nanostructure transistor (e.g., the top transistor TT) and that of the p-channel nanostructure transistor (e.g., the bottom transistor BT), a greater design flexibility for integrated circuits may be achieved. Therefore, depending on the types of the integrated circuits, the overall performance of integrated circuits can be improved by optimally adjusting the thickness difference between the nanostructures 108T and the nanostructures 108B.

For example, in the embodiments where the n-channel transistors (e.g., the top transistors TT) have a stronger saturation current than the p-channel transistors (e.g., bottom transistors BT), the semiconductor structure 100 may be used for SRAM cells, Footer cells, etc. For example, in the embodiments where the semiconductor structure 100 is used for high-current SRAM cells, the n-channel top transistors TT (e.g., functioning as the pull-down transistors and the pass-gate transistors) have stronger saturation current than the p-channel bottom transistors BT (e.g., functioning as the pull-up transistors), and thus the alpha ratio of the saturation current (PU Idsat/PG Idsat) may decrease, which may enhance cell performance (e.g., decrease in operation voltage (Vcc_min)) and/or expand write margin metric (e.g., increase in operation speed).

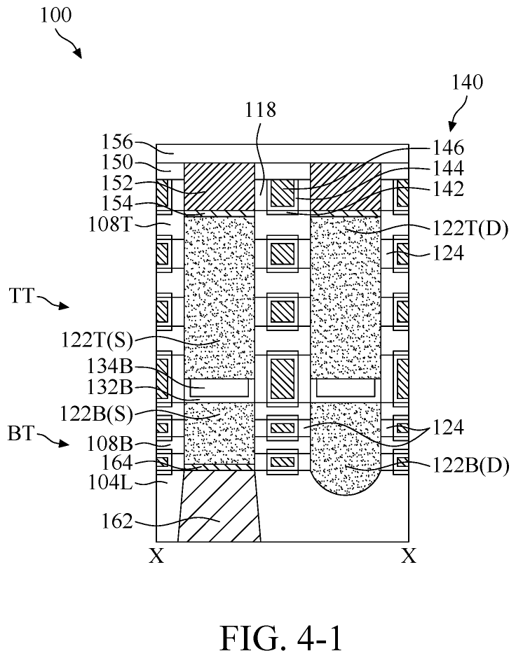

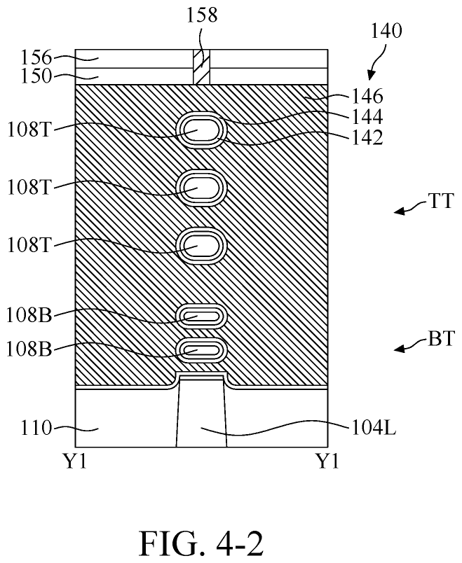

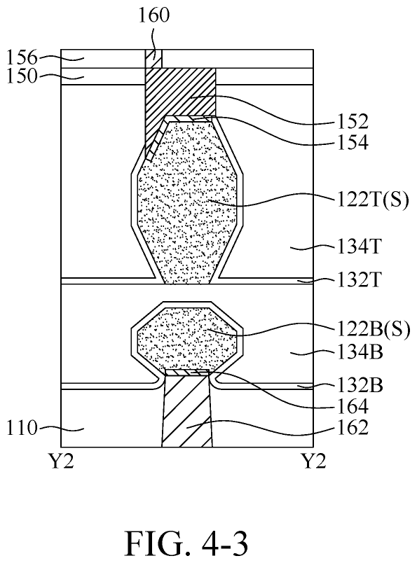

FIGS. 4-1, 4-2 and 4-3 are a modification of the semiconductor structure of FIGS. 3I-1, 3I-2 and 3I-3, in accordance with some embodiments of the disclosure. The embodiments of FIGS. 4-1 to 4-3 are similar to the embodiments of FIGS. 3A to 3I-3 except that the number of the nanostructures 108B of the bottom transistor BT is one less than or more than one less than the number of the nanostructures 108T of the top transistor TT.

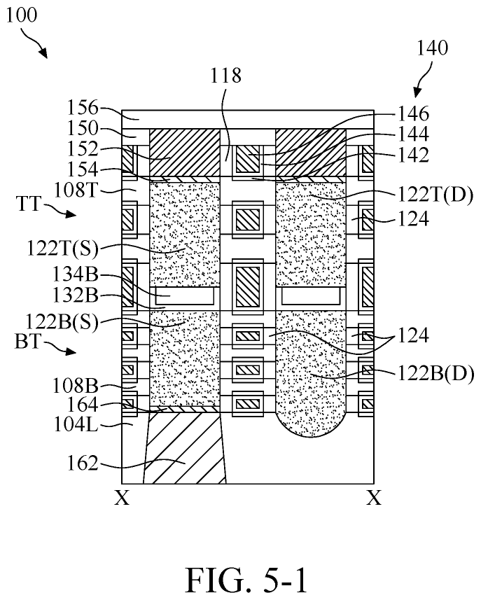

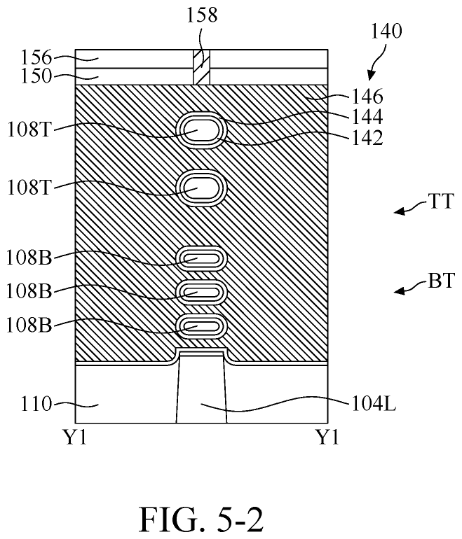

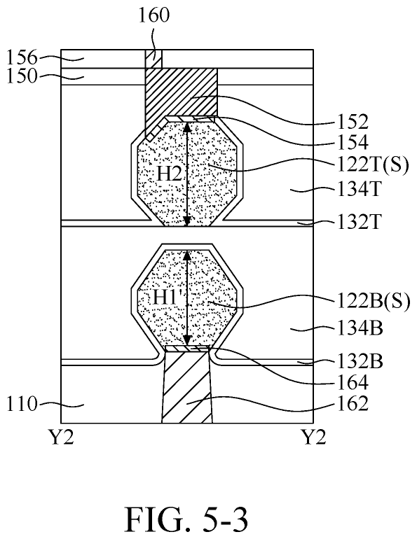

FIGS. 5-1, 5-2 and 5-3 are a modification of the semiconductor structure of FIGS. 3I-1, 3I-2 and 3I-3, in accordance with some embodiments of the disclosure. The embodiments of FIGS. 5-1 to 5-3 are similar to the embodiments of FIGS. 3A to 3I-3 except that the number of the nanostructures 108T of the top transistor TT is one less than or more than one less than the number of the nanostructures 108B of the bottom transistor BT. In some embodiments, the height H1′ of the bottom source/drain features 122B(S) may be less than, equal to, or greater than the height H2 of the top source/drain features 122T.

In accordance with the embodiments of the present disclosure, the nanostructures 108T of the top transistor TT have a different channel number than the nanostructures 108B of the bottom transistor BT, and thus the performance of the top transistor TT and that of the bottom transistor BT can be independently adjusted. Therefore, a greater design flexibility for integrated circuits may be achieved.

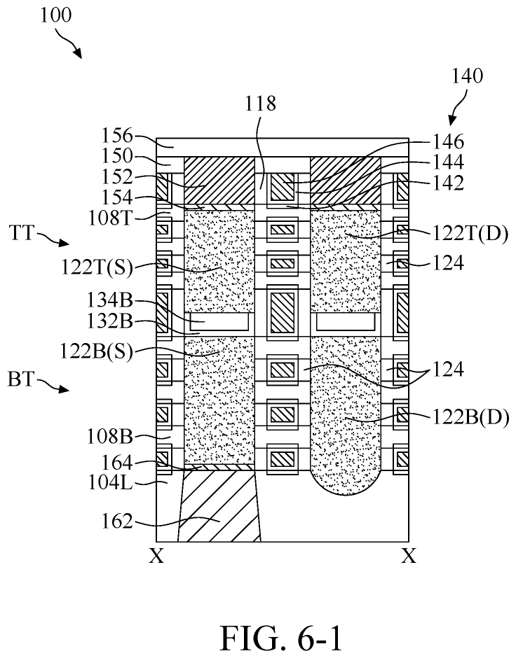

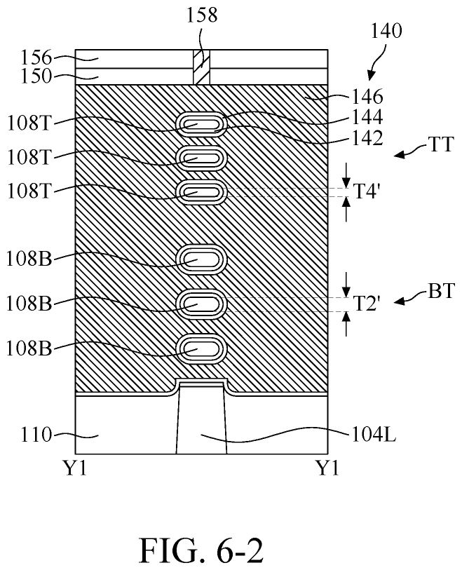

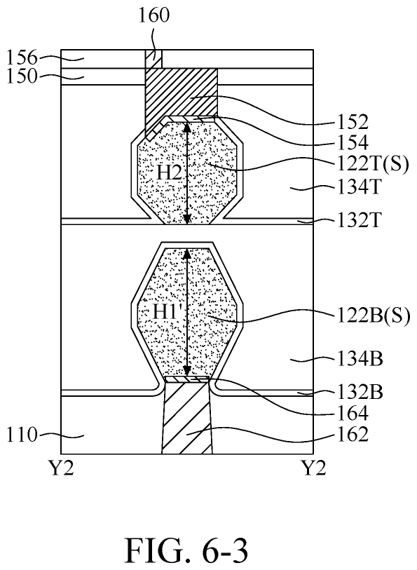

FIGS. 6-1, 6-2 and 6-3 are a modification of the semiconductor structure of FIGS. 3I-1, 3I-2 and 3I-3, in accordance with some embodiments of the disclosure. The embodiments of FIGS. 6-1 to 6-3 are similar to the embodiments of FIGS. 3A to 3I-3 except that the thickness T4′ of the nanostructures 108T of the top transistor TT is less than the thickness T2′ of the nanostructures 108B of the bottom transistor BT.

In some embodiments, each of the nanostructures 108B has the thickness T2′ in a range from about 3 nm to about 10 nm. In some embodiments, each of the nanostructures 108T has the thickness T4′ in a range from about 2 nm to about 9 nm. In some embodiments, the ratio of the thickness T4′ to thickness T2′ is greater than 0.2 and less than 1. In some embodiments, the height H1′ of the bottom source/drain features 122B(S) is greater than the height H2 of the top source/drain features 122T(S).

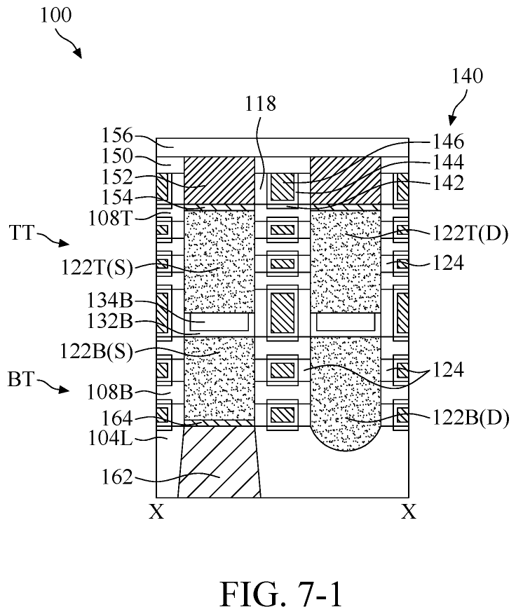

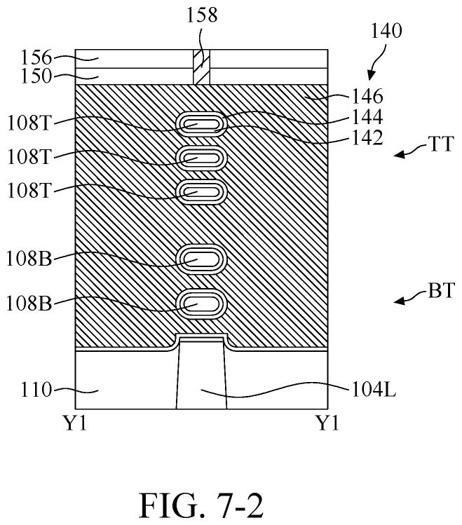

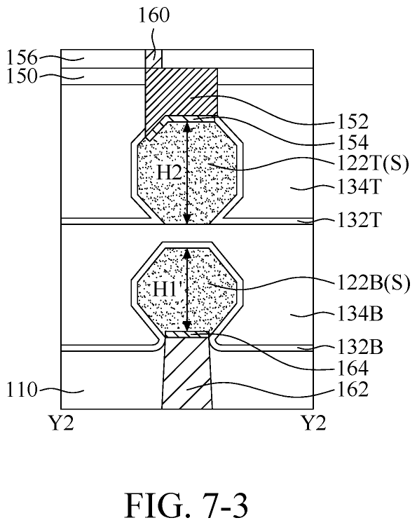

FIGS. 7-1, 7-2 and 7-3 are a modification of the semiconductor structure of FIGS. 6-1, 6-2 and 6-3, in accordance with some embodiments of the disclosure. The embodiments of FIGS. 7-1 to 7-3 are similar to the embodiments of FIGS. 6-1 to 6-3 except that the number of the nanostructures 108B of the bottom transistor BT is one less than, or more than one less than the number of the nanostructures 108T of the top transistor TT. In some embodiments, the height H1′ of the bottom source/drain features 122B(S) may be less than, equal to, or greater than the height H2 of the top source/drain features 122T(S).

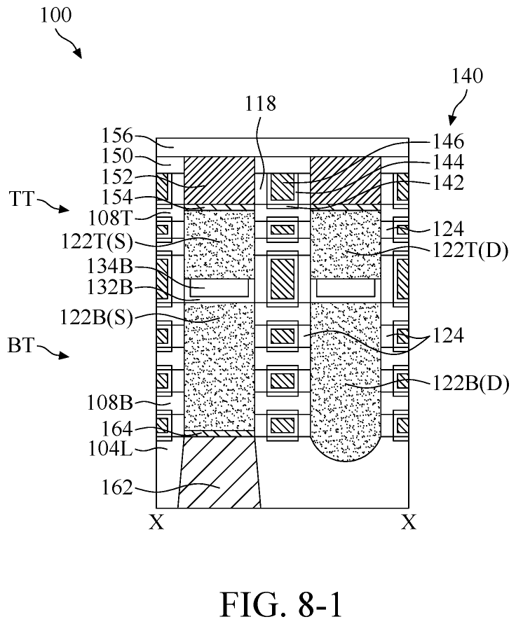

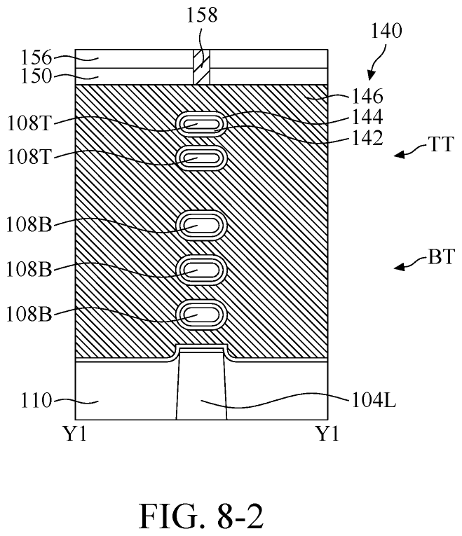

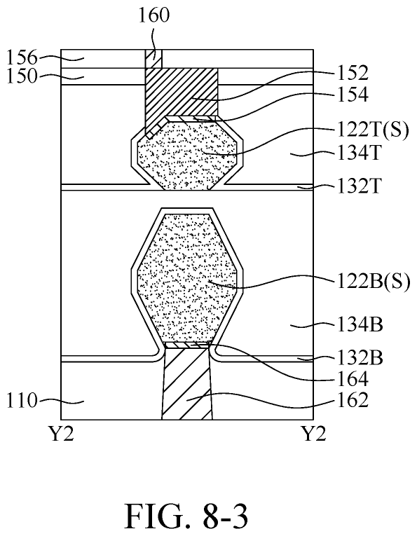

FIGS. 8-1, 8-2 and 8-3 are a modification of the semiconductor structure of FIGS. 6-1, 6-2 and 6-3, in accordance with some embodiments of the disclosure. The embodiments of FIGS. 8-1 to 8-3 are similar to the embodiments of FIGS. 6-1 to 6-3 except that the number of the nanostructures 108T of the top transistor TT is one less than, or more than one less than the number of the nanostructures 108B of the bottom transistor BT.

In accordance with some embodiments of the present disclosure, the nanostructures 108T of the top transistor TT have a different thickness and/or channel number than the nanostructures 108B of the bottom transistor BT, and thus the performance of the top transistor TT and that of the bottom transistor BT can be independently adjusted. Therefore, a greater design flexibility for integrated circuits may be achieved. For example, in the embodiments where the p-channel transistors (e.g., bottom transistors BT) have a stronger saturation current than the n-channel transistors (e.g., the top transistors TT), the semiconductor structure 100 may be used for Header cells, etc.

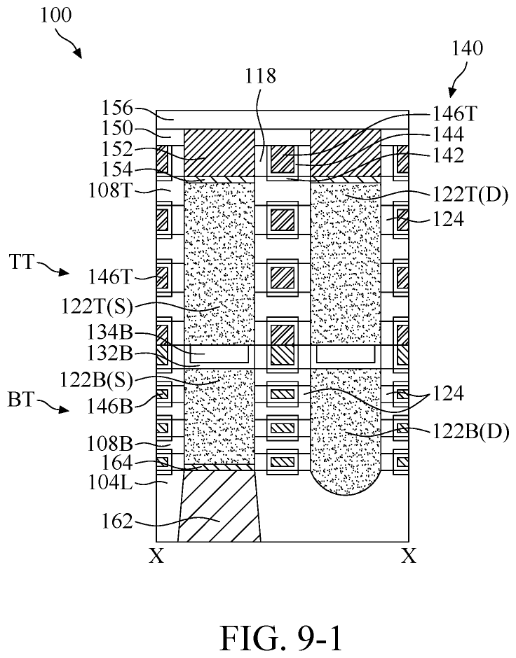

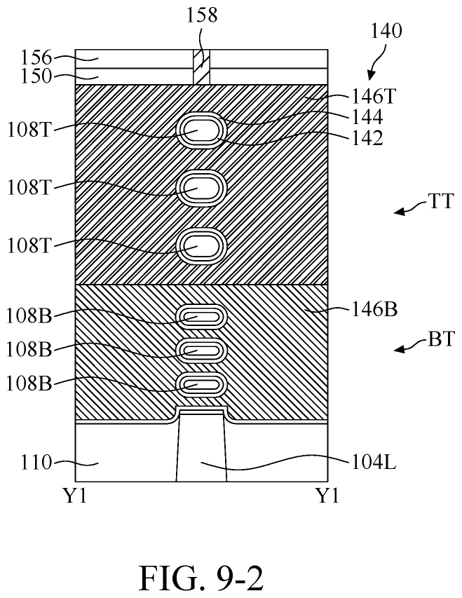

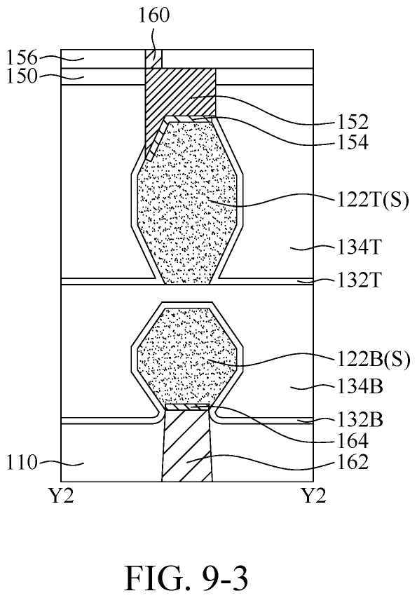

FIGS. 9-1, 9-2 and 9-3 are a modification of the semiconductor structure of FIGS. 3I-1, 3I-2 and 3I-3, in accordance with some embodiments of the disclosure. The embodiments of FIGS. 9-1 to 9-3 are similar to the embodiments of FIGS. 3A to 3I-3 except that the metal gate electrode layer 146 includes a bottom work function layer 146B and a top work function layer 146T.

After the gate dielectric layer 142 is formed, a bottom work function layer 146B is formed to overfill of the gate trenches 136 and gaps 138, and etched back to expose the nanostructures 108T, in accordance with some embodiments. A top work function layer 146T is formed over the bottom work function layer 146B to surround the nanostructures 108T, as shown in FIGS. 9-1 and 9-2, in accordance with some embodiments. In some embodiments where the bottom transistor BT is a p-channel FET and the top transistor TT is an n-channel FET, the bottom work function layer 146B is a p-type work function metal, and the top work function layer 146T is an n-type work function metal.

As used herein, the term “n-type work function metal” defines a metal or a metal-containing material with a work function that is closer to a conduction band energy than a valence band energy of semiconductor material of a FET channel region. In some embodiments, the term “n-type work function metal” defines a metal or a metal-containing material with a work function of less than 4.5 eV. The term “p-type work function metal” defines a metal or a metal-containing material with a work function that is closer to a valence band energy than a conduction band energy of a semiconductor material of a FET channel region. In some embodiments, the term “p-type work function metal” defines a metal or a metal-containing material with a work function that is equal to or greater than 4.5 eV.

In some embodiments, the top transistor TT and the bottom transistor BT use different work function layers 146T and 146B, and thus the performance of the top transistor TT and that of the bottom transistor BT can be independently adjusted. Therefore, a greater design flexibility for integrated circuits may be achieved.

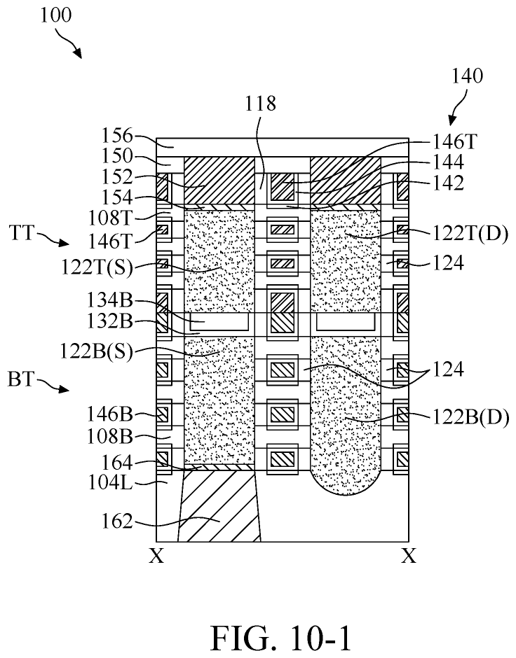

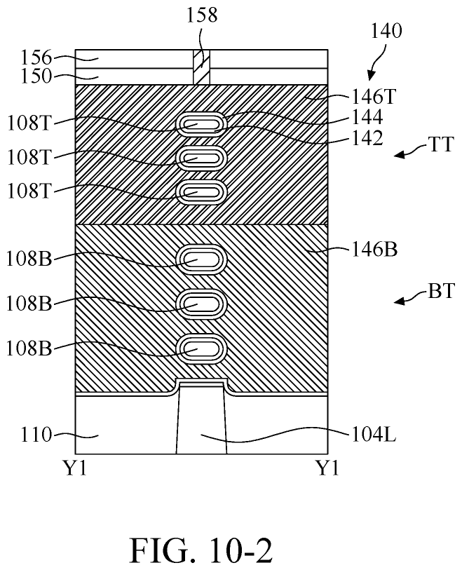

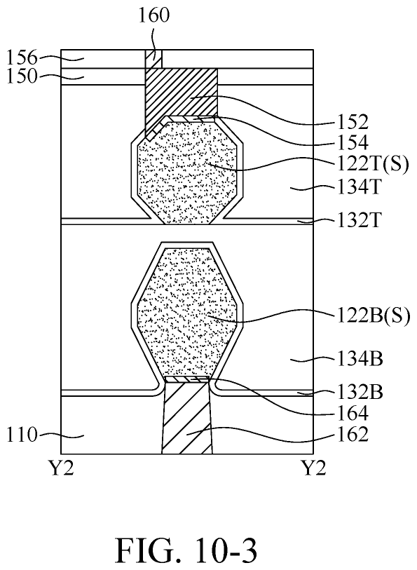

FIGS. 10-1, 10-2 and 10-3 are a modification of the semiconductor structure of FIGS. 6-1, 6-2 and 6-3, in accordance with some embodiments of the disclosure. The embodiments of FIGS. 10-1 to 10-3 are similar to the embodiments of FIGS. 6-1 to 6-3 except that the gate electrode layer 146 includes a bottom work function layer 146B and a top work function layer 146T. In some embodiments where the bottom transistor BT is a p-channel FET and the top transistor TT is an n-channel FET, the bottom work function layer 146B is a p-type work function metal, and the top work function layer 146T is an n-type work function metal.

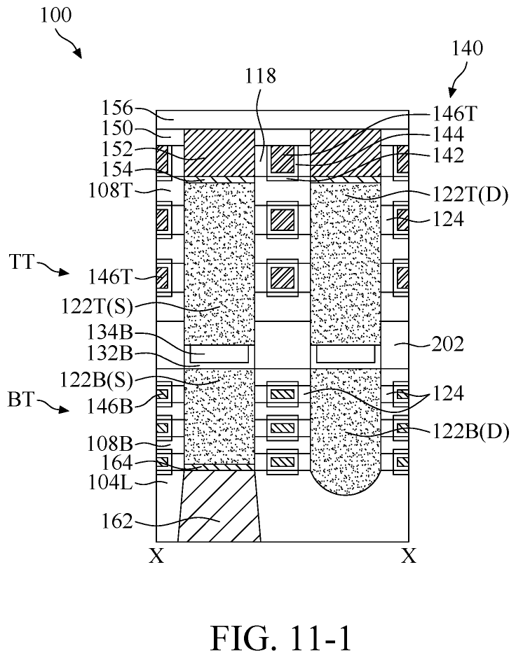

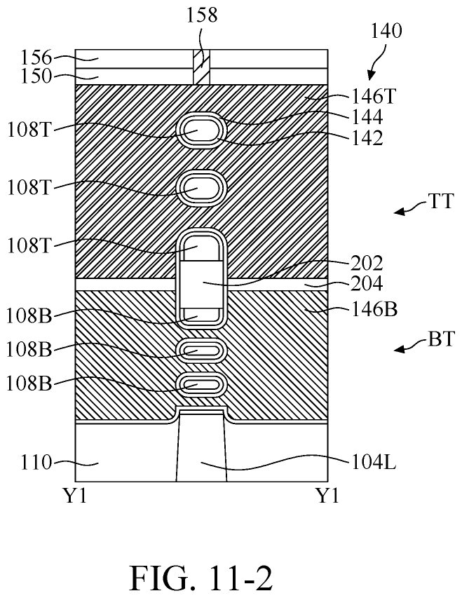

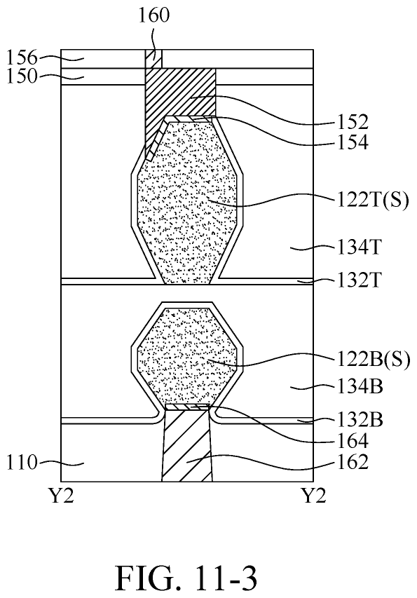

FIGS. 11-1, 11-2 and 11-3 are a modification of the semiconductor structure of FIGS. 9-1, 9-2 and 9-3, in accordance with some embodiments of the disclosure. The embodiments of FIGS. 11-1 to 11-3 are similar to the embodiments of FIGS. 9-1 to 9-3 except that the bottom work function layer 146B is separated from the top work function layer 146T.

During the steps for forming the inner spacer layers 124, the middle layer 109 is completely removed to form gaps, and the dielectric material for the inner spacer layers 124 fills the gaps to form isolation layers 202 between the topmost second semiconductor layers 108B and bottommost second semiconductor layers 108T, in accordance with some embodiments.

After the bottom work function layer 146B is etched back, an isolation layer 204 is deposited over semiconductor structure 100 and etched back, in accordance with some embodiments. In some embodiments, the isolation layer 204 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. The top work function layer 146T is then formed over the isolation layer 204 to surround the nanostructures 108T, in accordance with some embodiments. The bottom work function layer 146B is physically and electrically isolated from the top work function layer 146T by the isolation layers 202 and 204, in accordance with some embodiments.

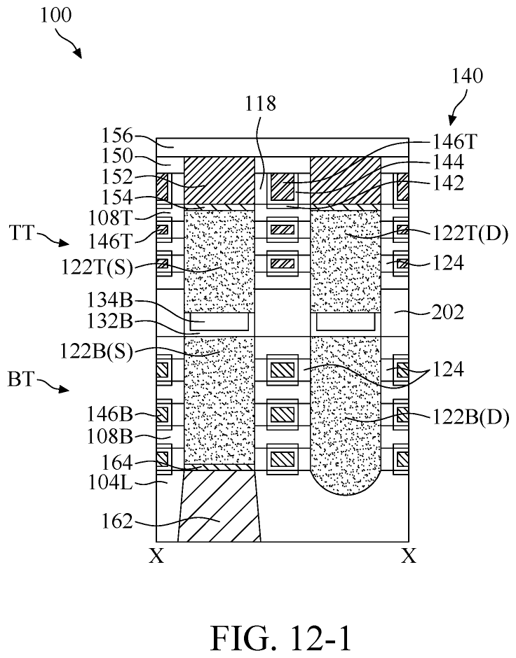

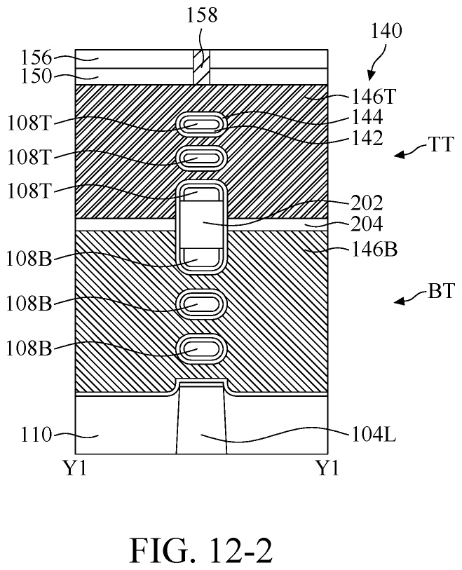

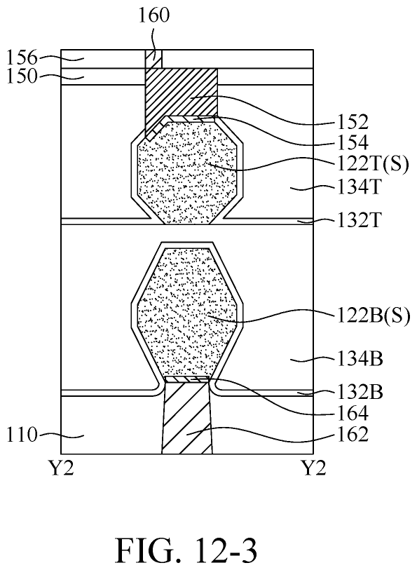

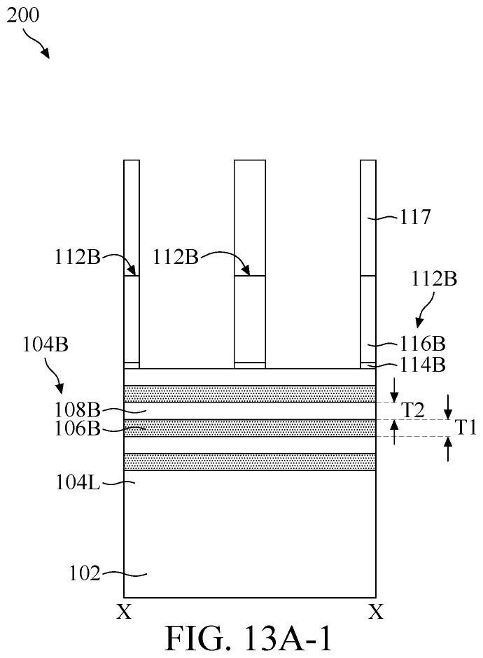

FIGS. 12-1, 12-2 and 12-3 are a modification of the semiconductor structure of FIGS. 10-1, 10-2 and 10-3, in accordance with some embodiments of the disclosure. The embodiments of FIGS. 12-1 to 12-3 are similar to the embodiments of FIGS. 10-1 to 10-3 except that the bottom work function layer 146B is separated from the top work function layer 146T by isolation layers 202 and 204. In some embodiments, the formation of the isolation layers 202 and 204 is the same as or similar to the formation of the isolation layers 202 and 204 described above in FIGS. 11-1 to 11-3.

FIGS. 13A-1 through 13D-3 are cross-sectional views illustrating the formation of the semiconductor structure of FIG. 2 at various intermediate stages, in accordance with some embodiments of the disclosure.

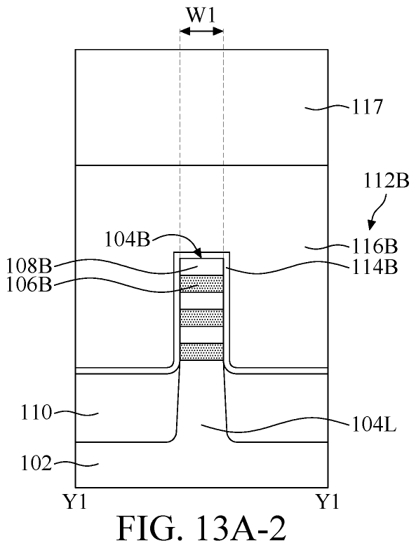

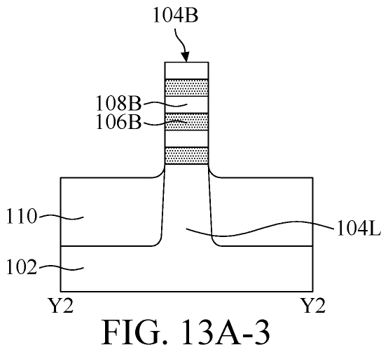

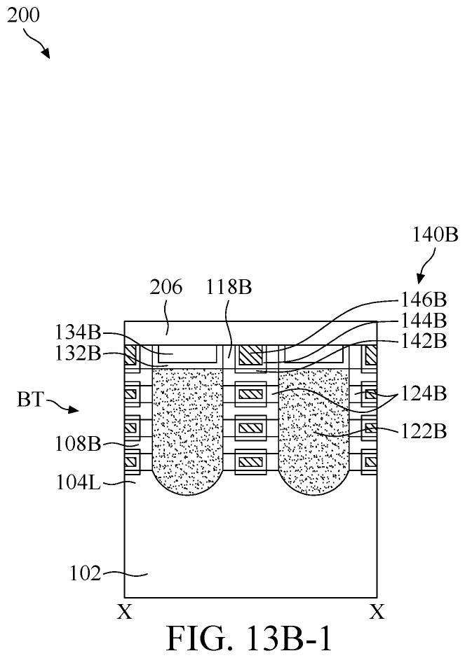

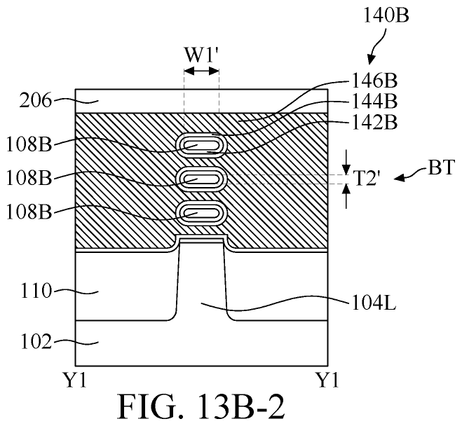

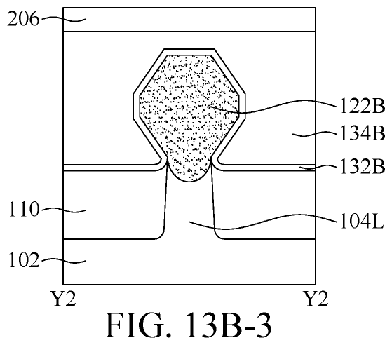

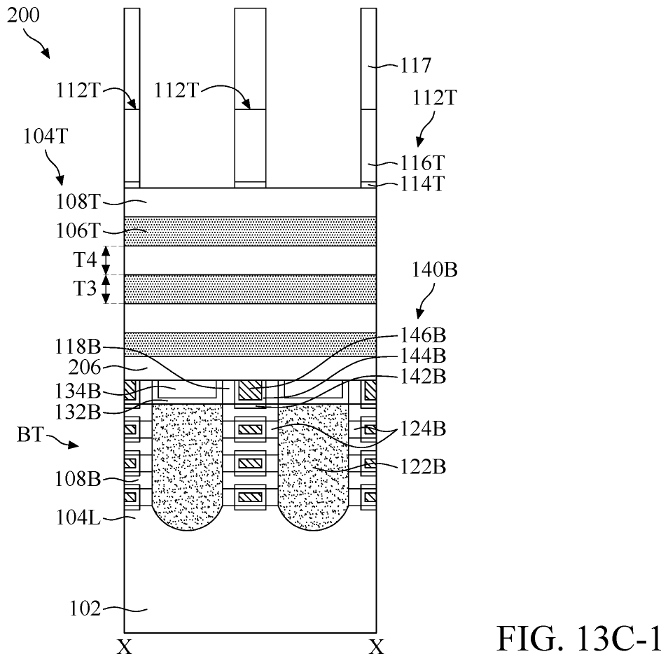

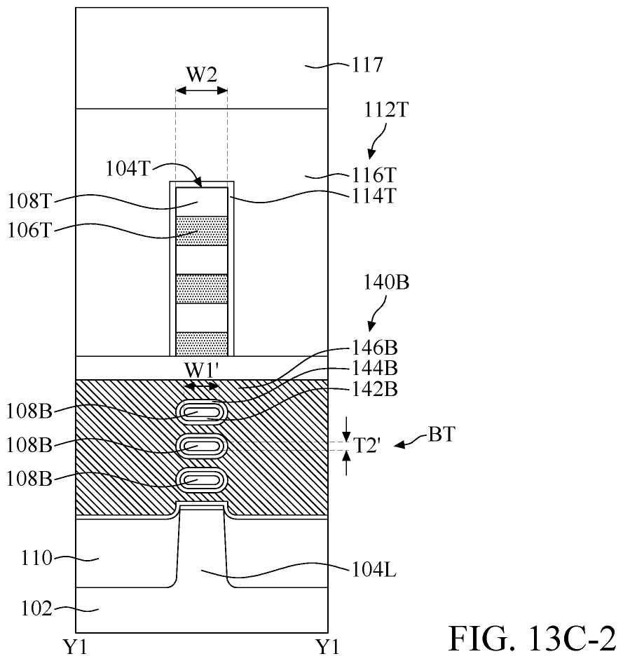

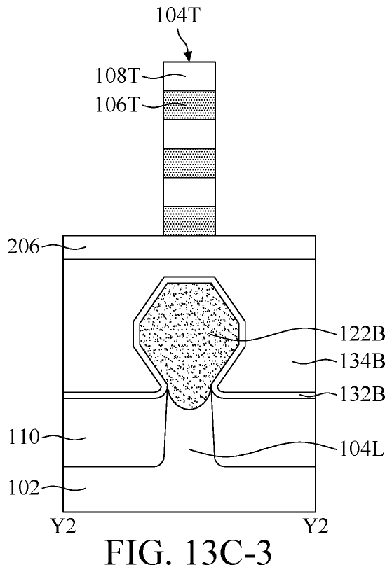

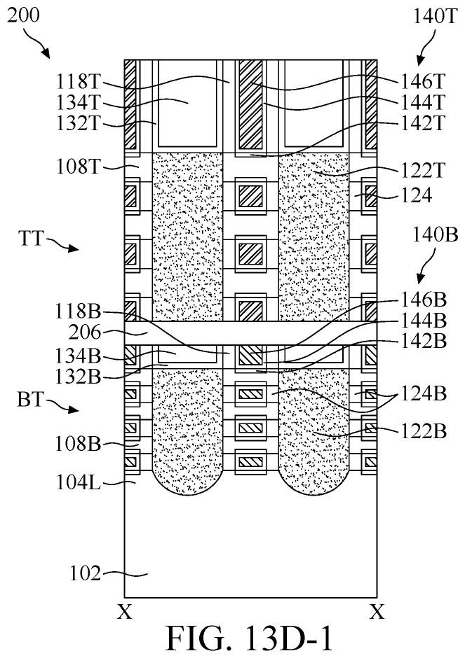

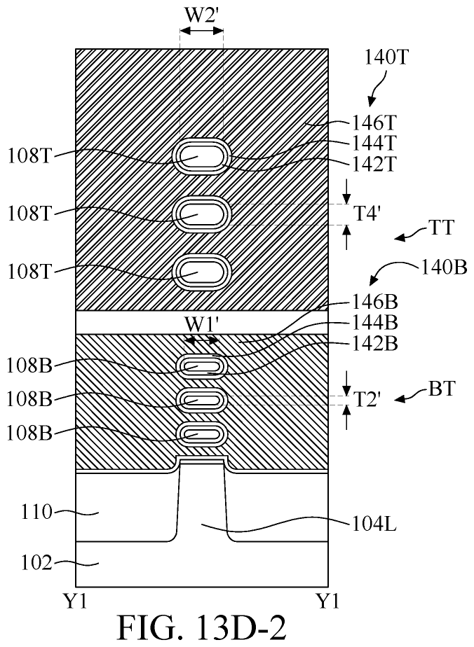

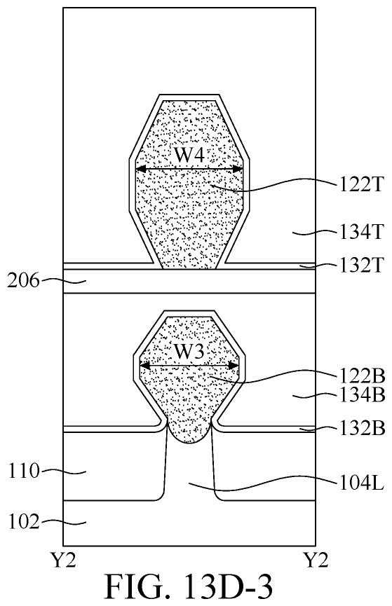

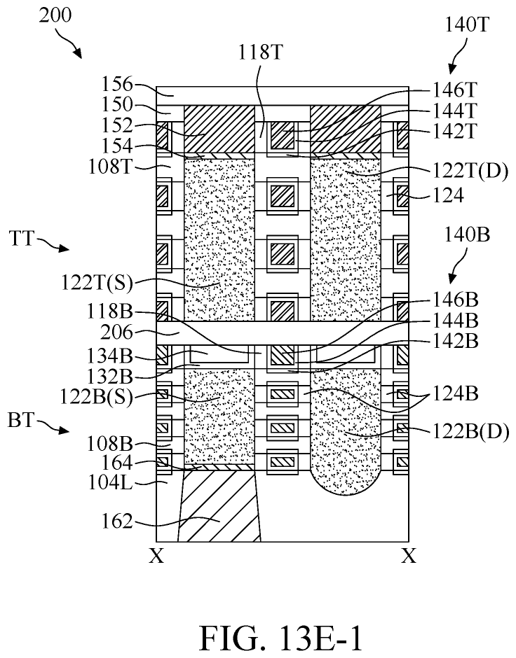

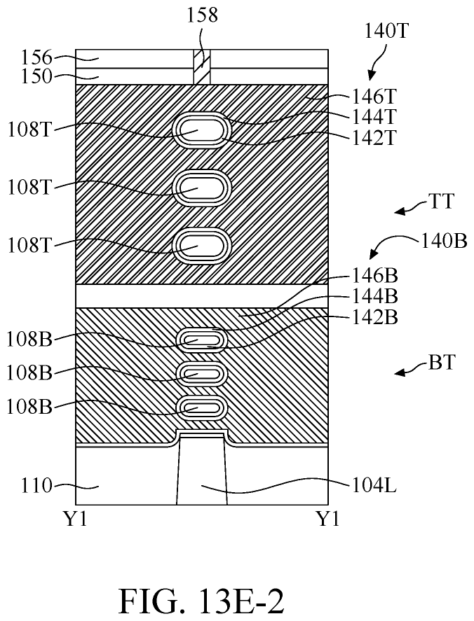

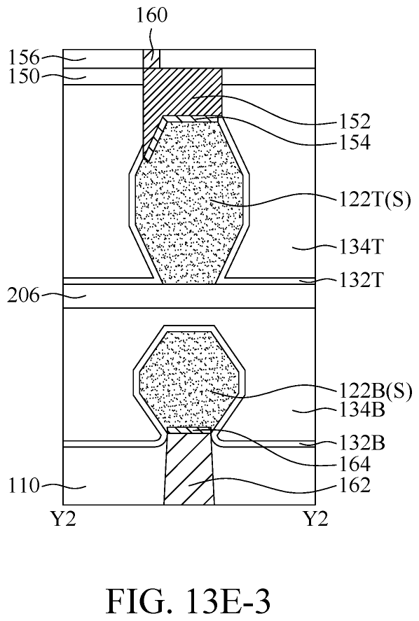

FIGS. 13A through 13E-3 illustrates the formation of a semiconductor structure 200 at various intermediate stages, in that FIGS. 13A-1, 13B-1, 13C-1, 13D-1 and 13E-1 correspond to line X-X of FIG. 2, FIGS. 13A-2, 13B-2, 13C-2, 13D-2 and 13E-2 correspond to line Y1-Y1 of FIG. 2, and FIGS. 13A-3, 13B-3, 13C-3, 13D-3 and 13E-3 correspond to line Y2-Y2 of FIG. 2, in accordance with some embodiments of the disclosure.

FIGS. 13A-1, 13A-2 and 1A-3 illustrate the semiconductor structure 200 after the formation of a fin structure 104B, an isolation structure 110 and dummy gate structures 112B, in accordance with some embodiments.

An active region 104B is formed over the substrate 102, as shown in FIGS. 13A-1 to 13A-3, in accordance with some embodiments. The active region 104B includes a lower fin element 104L and first semiconductor layers 106B and the second semiconductor layers 108B alternately stacked over the lower fin element 104L, in accordance with some embodiments. In some embodiments, the materials and the formation of the active region 104B are the similar to the materials and the formation of the bottom device region of the active region 104 described above. In some embodiments, each of the second semiconductor layers 108B has a width W1 in a range from about 5.5 nm to about 60 nm.

The isolation structure 110 is formed to surround the lower fin element 104L of the active region 104B, and dummy gate structures 112B (including a dummy gate dielectric layer 114B and a dummy gate electrode layer 116B) are formed across the active region 104B and the isolation structure 110, as shown in FIGS. 13A-1 and 13A-2, in accordance with some embodiments. In some embodiments, the materials and the formation of the isolation structure 110 and the dummy gate structures 112B are the similar to the materials and the formation of the isolation structure 110 and the dummy gate structures 112 described above.

FIGS. 13B-1, 13B-2 and 13B-3 illustrate the semiconductor structure 200 after the formation of bottom transistors BT and a bonding dielectric material 206, in accordance with some embodiments.

Gate spacer layers 118B are formed along opposite sidewalls of the dummy gate structures 112B, the bottom source/drain features 122B are formed on the side surfaces of the second semiconductor layers 108B and the top surface of the lower fin element 104L, and the inner spacer layers 124B are formed on the sidewalls of the first semiconductor layers 106B, as shown in FIGS. 13B-1 to 13B-3, in accordance with some embodiments. In some embodiments, the materials and the formation of the gate spacer layers 118B, the bottom source/drain features 122B and the inner spacer layers 124B are the similar to the materials and the formation of the gate spacer layers 118, the bottom source/drain features 122B and the inner spacer layers 124 described above.

The contact etching stop layer 132B and the first interlayer dielectric layer 134B are formed to cover the bottom source/drain features 122B, and the dummy gate structures 112B and the first semiconductor layers 106B are removed to form nanostructures 108B, as shown in FIGS. 13B-1 to 13B-3, in accordance with some embodiments. In some embodiments, each of the nanostructures 108B has a width W1′ in a range from about 5.5 nm to about 60 nm.

The bottom final gate stacks 140B are formed to surround the nanostructures 108B, thereby forming bottom transistors BT, as shown in FIGS. 13B-1 to 13B-3, in accordance with some embodiments. In some embodiments, the bottom final gate stacks 140B includes an interfacial layer 142B, a gate dielectric layer 144B and a bottom work function layer 146B (which may serve as the metal gate electrode layer for the bottom transistors BT), in accordance with some embodiments. In some embodiments, the materials and the formation of the contact etching stop layer 132B, the first interlayer dielectric layer 134B and the bottom final gate stack 140B are the similar to the materials and the formation of the contact etching stop layer 132B, the first interlayer dielectric layer 134B and the final gate stack 140 described above.

A bonding dielectric material 206 is formed over the semiconductor structure 200, as shown in FIGS. 13B-1 to 13B-3, in accordance with some embodiments. In some embodiments, the bonding dielectric material 206 is made silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), AlN, BN, SiC, BeO, or a combination thereof. In some embodiments, the bonding dielectric material 206 is deposited using CVD (such as LPCVD, PECVD, or HDP-CVD), ALD, another suitable technique, or a combination thereof.

FIGS. 13C-1, 13C-2 and 13C-3 illustrate the semiconductor structure 200 after the formation of a fin structure 104T and dummy gate structures 112T, in accordance with some embodiments.

An active region 104T is formed over the bonding dielectric material 206, as shown in FIGS. 13C-1 to 13C-3, in accordance with some embodiments. The active region 104T is aligned over the nanostructures 108B and lower fin element 104L, in accordance with some embodiments. In some embodiment, the formation of the active region 104T includes forming a stack including alternating first semiconductor layers 106T and the second semiconductor layers 108T on a carrier substrate (not shown), bonding the frontside of the carrier substrate onto the bonding dielectric material 206, and removing the carrier substrate. The stack is then patterned into the active region 104T using photolithography and etching processes.

In some embodiments, the second semiconductor layers 108B and the second semiconductor layers 108T are made of the same material, such as Si. In some embodiments, the second semiconductor layers 108B and the second semiconductor layers 108T are made of different materials, for example, the second semiconductor layers 108B are made of SiGe, and the second semiconductor layers 108T are made of Si.

In some embodiments, each of the second semiconductor layers 108T has a width W2 in a range from about 6 nm to about 65 nm. In some embodiments, the second semiconductor layers 108T are greater than the second semiconductor layers 108B, i.e., W2>W1 (or W1′). In some embodiments, the ratio of the width W2 to width W1 is greater than 1 and less than 5, e.g., in a range from about 1.1 to about 3.

Dummy gate structures 112T are formed across the active region 104T, as shown in FIGS. 13C-1 and 13C-2, in accordance with some embodiments. In some embodiments, the materials and the formation of the dummy gate structures 112T are the similar to the materials and the formation the dummy gate structures 112 described above.

FIGS. 13D-1, 13D-2 and 13D-3 illustrate the semiconductor structure 200 after the formation of top transistors TT, in accordance with some embodiments.

Gate spacer layers 118T are formed along opposite sidewalls of the dummy gate structures 112T, the top source/drain features 122T are formed on the side surfaces of the second semiconductor layers 108T, and the inner spacer layers 124T are formed on the sidewalls of the first semiconductor layers 106T, as shown in FIGS. 13D-1 to 13D-3, in accordance with some embodiments. In some embodiments, the materials and the formation of the gate spacer layers 118T, the bottom source/drain features 122T and the inner spacer layers 124T are the similar to the materials and the formation of the gate spacer layers 118, the bottom source/drain features 122T and the inner spacer layers 124 described above. In some embodiments, the width W3 of the bottom source/drain features 122B is less than the width W4 of the top source/drain features 122T.

The contact etching stop layer 132T and the first interlayer dielectric layer 134T are formed to cover the top source/drain features 122T, and the dummy gate structures 112T and the first semiconductor layers 106T are removed to form nanostructures 108T, as shown in FIGS. 13D-1 to 13D-3, in accordance with some embodiments. In some embodiments, each of the nanostructures 108T has a width W2′ in a range from about 6 nm to about 65 nm. In some embodiments, the nanostructures 108T of the top transistor TT are greater than the nanostructures 108B of the bottom transistor BT, i.e., W2′>W1′. In some embodiments, the ratio of the width W2′ to width W1′ is greater than 1 and less than 5, e.g., in a range from about 1.1 to about 3. In addition, in some embodiments, the nanostructures 108T are thicker than the nanostructures 108B in the bottom device region, i.e., T4′>T2′.

The top final gate stack 140T is formed to surround the nanostructures 108T, thereby forming top transistors TT, as shown in FIGS. 13D-1 to 13D-3, in accordance with some embodiments. In some embodiments, the top final gate stack 140T includes an interfacial layer 142T, a gate dielectric layer 144T and a top work function layer 146T (which may serve as the metal gate electrode layer for the top transistors TT), in accordance with some embodiments. In some embodiments, the materials and the formation of the contact etching stop layer 132T, the first interlayer dielectric layer 134T and the top final gate stack 140T are the similar to the materials and the formation of the contact etching stop layer 132T, the first interlayer dielectric layer 134T and the final gate stack 140 described above.

FIGS. 13E-1, 3E-2 and 13E-3 illustrate the semiconductor structure 200 after the formation of a second interlayer dielectric layer 150, contact plugs 152, a third interlayer dielectric layer 156, vias 158 and 160, and a backside contact plug 162, in accordance with some embodiments.

In some embodiments, the steps described above in FIGS. 3I-1 to 3I-3 are performed, thereby forming a second interlayer dielectric layer 150, contact plugs 152, a third interlayer dielectric layer 156, vias 158 and 160, and a backside contact plug 162, as shown in FIGS. 13E-1, 3E-2 and 13E-3, in accordance with some embodiments.

In accordance with some embodiments of the present disclosure, the nanostructures 108T of the top transistor TT have a different thickness and width than the nanostructures 108B of the bottom transistor BT, and thus the performance of the top transistor TT and that of the bottom transistor BT can be independently adjusted. Therefore, a greater design flexibility for integrated circuits may be achieved.

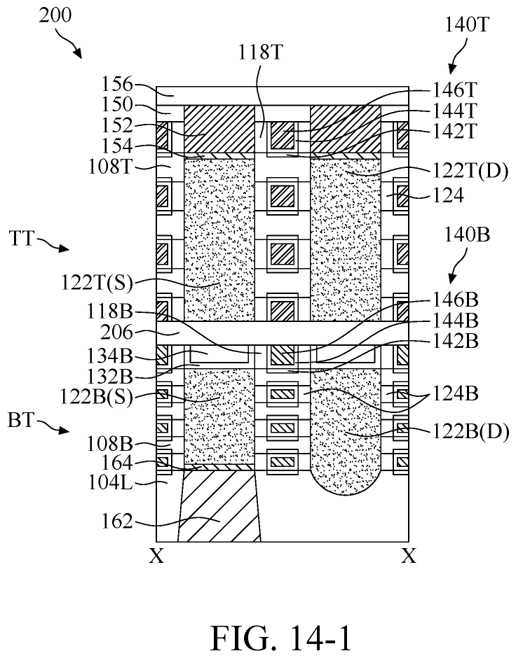

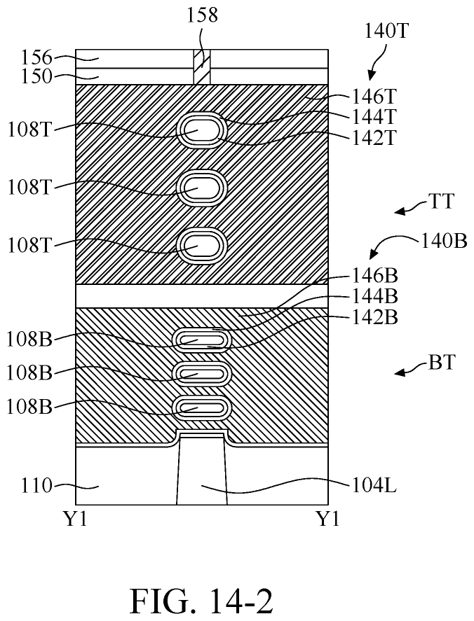

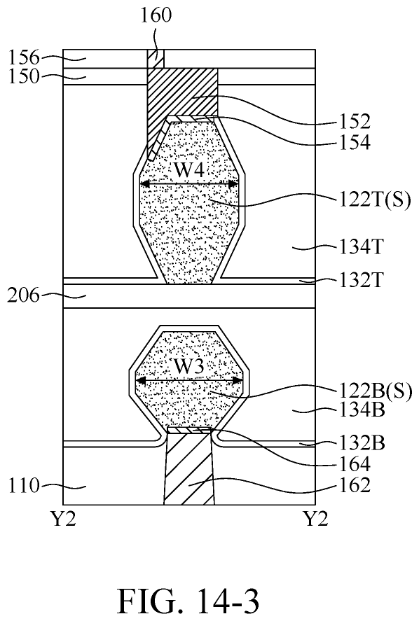

FIGS. 14-1, 14-2 and 14-3 are a modification of the semiconductor structure of FIGS. 13E-1, 13E-2 and 13E-3, in accordance with some embodiments of the disclosure. The embodiments of FIGS. 14-1 to 14-3 are similar to the embodiments of FIGS. 13A-1 to 13E-3 except that the width W2′ of the nanostructures 108T of the top transistor TT is less than the width W1′ of the nanostructures 108B of the bottom transistor BT.

In some embodiments, each of the nanostructures 108B has a width W1′ in a range from about 6 nm to about 65 nm. In some embodiments, each of the nanostructures 108T has a width W2′ in a range from about 5.5 nm to about 60 nm. In some embodiments, the ratio of the width W1′ to width W2′ is greater than 1 and less than 5, e.g., in a range from about 1.1 to about 3. In some embodiments, the width W3 of the bottom source/drain features 122B is greater than the width W4 of the top source/drain features 122T.

As described above, the semiconductor structure includes CFET device, and each of the CFET devices includes a bottom transistor BT and top transistor TT. The thickness T4′ of the nanostructure 108T of the top transistor TT is different than the thickness T2′ of the nanostructure 108B of the bottom transistor BT, and thus the performance of the top transistor TT and that of the bottom transistor BT can be independently adjusted. Therefore, a greater design flexibility for integrated circuits may be achieved.

In addition, the number of the nanostructure 108T may be different than the number of the nanostructure 108B; the materials of the nanostructure 108T may be different than the nanostructure 108B; the width W2′ of the nanostructure 108T may be different than the width W1′ of the nanostructure 108B; and/or the gate electrode material of the top transistor TT may be different than the gate electrode material of the bottom transistor BT, in accordance with some embodiments. Therefore, depending on the types of the resulting integrated circuits, the overall performance of integrated circuits can be improved by optimally adjusting these differences.

Embodiments of a semiconductor structure and the method for forming the same may be provided. The method for forming the semiconductor structure may include forming a stack in which lower sacrificial layers and lower channel layers are alternately stacked in the bottom device region of the stack, and the upper sacrificial layers and upper channel layers are alternately stacked in the top device region of the stack over the bottom device region. The thickness of the lower channel layers is different than the thickness of the upper channel layers. Therefore, the performance of the top transistor and that of the bottom transistor may be independently adjusted, thereby improving the overall performance of the resulting integrated circuits.

In some embodiments, a method for forming a semiconductor structure is provided. The method includes forming a bottom transistor over a substrate, and forming a top transistor above the bottom transistor. The bottom transistor includes a first nanostructure, a first source/drain feature adjoining the first nanostructure and a first work function layer wrapping the first nanostructure. The top transistor includes a second nanostructure, a second source/drain feature adjoining the second nanostructure and a second work function layer wrapping the second nanostructure. The first source/drain feature is physically isolated from the second source/drain feature, and a first thickness of the first nanostructure is different than a second thickness of the second nanostructure.

In some embodiments, a method for forming a semiconductor structure is provided. The method includes forming a stack in which lower sacrificial layers and lower channel layers are alternatingly stacked in a bottom device region of the stack, and upper sacrificial layers and upper channel layers are alternatingly stacked in a top device region of the stack over the bottom device region. A first thickness of the lower channel layers is different than a second thickness of the upper channel layers. The method further includes patterning the stack to form a fin structure, removing the lower sacrificial layers and the upper sacrificial layers to expose the lower channel layers and the upper channel layers, and forming a gate stack surrounding the lower channel layers and the upper channel layers.

In some embodiments, a semiconductor structure is provided. The semiconductor structure includes a bottom transistor, and a top transistor above the bottom transistor. The bottom transistor includes a plurality of first nanostructures, a first source/drain feature adjoining the plurality of first nanostructures and a first gate stack wrapping the plurality of first nanostructures. The top transistor includes a plurality of second nanostructures, a second source/drain feature adjoining the plurality of second nanostructures and a second gate stack wrapping the plurality of second nanostructures, wherein a first thickness of the first nanostructures is different than a second thickness of the second nanostructures. The semiconductor structure further includes an interlayer dielectric layer interposing between the first source/drain feature and the second source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a bottom transistor over a substrate, wherein the bottom transistor comprises a first nanostructure, a first source/drain feature adjoining the first nanostructure and a first work function layer wrapping the first nanostructure; and
forming a top transistor above the bottom transistor, wherein the top transistor comprises a second nanostructure, a second source/drain feature adjoining the second nanostructure and a second work function layer wrapping the second nanostructure,
wherein the first source/drain feature is physically isolated from the second source/drain feature, and a first thickness of the first nanostructure is different than a second thickness of the second nanostructure.

2. The method for forming the semiconductor structure as claimed in claim 1, wherein the first source/drain feature is doped with a p-type dopant, and the second source/drain feature is doped with an n-type dopant.

3. The method for forming the semiconductor structure as claimed in claim 1, further comprising:
forming a first active region over the substrate;
patterning the first active region to form the first nanostructure;
forming the first work function layer to wrap the first nanostructure;
bonding a bonding dielectric material over the first work function layer;
forming a second active region over the bonding dielectric material;
patterning the second active region to form the second nanostructure; and
forming the second work function layer to wrap the second nanostructure.

4. The method for forming the semiconductor structure as claimed in claim 3, wherein a first width of the first fin structure is different than a second width of the second fin structure.

5. The method for forming the semiconductor structure as claimed in claim 1, wherein the first work function layer and the second work function layer are made of different materials.

6. A method for forming a semiconductor structure, comprising:
forming a stack in which lower sacrificial layers and lower channel layers are alternatingly stacked in a bottom device region of the stack, and upper sacrificial layers and upper channel layers are alternatingly stacked in a top device region of the stack over the bottom device region, wherein a first thickness of the lower channel layers is different than a second thickness of the upper channel layers;
patterning the stack to form a fin structure;
removing the lower sacrificial layers and the upper sacrificial layers to expose the lower channel layers and the upper channel layers; and
forming a gate stack surrounding the lower channel layers and the upper channel layers.

7. The method for forming the semiconductor structure as claimed in claim 6, further comprising:
recessing the fin structure to form a source/drain recess;
forming a bottom source/drain feature adjoining the lower channel layers in the source/drain recess;
forming a lower interlayer dielectric layer to cover the lower source/drain feature; and
forming a top source/drain feature adjoining the upper channel layers in the source/drain recess, wherein the top source/drain feature has a different conductivity type than the bottom source/drain feature.

8. The method for forming the semiconductor structure as claimed in claim 7, further comprising:
forming a first contact plug on a top surface of the top source/drain feature; and
forming a second contact plug on a bottom surface of the bottom source/drain feature.

9. The method for forming the semiconductor structure as claimed in claim 6, wherein a first height of the bottom source/drain feature is different than a second height of the top source/drain feature.

10. The method for forming the semiconductor structure as claimed in claim 6, wherein there is a different number of lower channel layers than upper channel layers.

11. The method for forming the semiconductor structure as claimed in claim 6, wherein forming the gate stack comprises:
forming a bottom work function layer surrounding the lower channel layers and the upper channel layers; and
forming a top work function layer surrounding the upper channel layers, wherein the bottom work function layer is made of a different material than the top work function layer.

12. The method for forming the semiconductor structure as claimed in claim 11, further comprising:
forming an isolation layer between the bottom work function layer and the top work function layer.

13. The method for forming the semiconductor structure as claimed in claim 6, wherein the lower channel layers are made of a different material than the upper channel layers.

14. The method for forming the semiconductor structure as claimed in claim 6, wherein each of the upper channel layers is thicker than each of the lower channel layers.

15. A semiconductor structure, comprising:
a bottom transistor comprising a plurality of first nanostructures, a first source/drain feature adjoining the plurality of first nanostructures and a first gate stack wrapping the plurality of first nanostructures;
a top transistor above the bottom transistor, comprising a plurality of second nanostructures, a second source/drain feature adjoining the plurality of second nanostructures and a second gate stack wrapping the plurality of second nanostructures, wherein a first thickness of the first nanostructures is different than a second thickness of the second nanostructures; and
an interlayer dielectric layer interposing between the first source/drain feature and the second source/drain feature.

16. The semiconductor structure as claimed in claim 15, wherein the plurality of second nanostructures overlaps the plurality of first nanostructures, and the second source/drain feature overlaps the first source/drain feature.

17. The semiconductor structure as claimed in claim 15, wherein the first gate stack includes a p-type work function layer, and the second gate stack includes an n-type work function layer.

18. The semiconductor structure as claimed in claim 15, wherein there is a different number of first nanostructures than second nanostructures.

19. The semiconductor structure as claimed in claim 15, wherein a first width of the first nanostructures is different than a second width of the second nanostructures.

20. The semiconductor structure as claimed in claim 15, wherein the first source/drain feature is electrically connected to a Vdd power rail, and the second source/drain feature is electrically connected to a Vss power rail.
